(19) United States
(12) Patent Application Publication
(10) Pub. No.: US 2026/0026120 A1
(43) Pub. Date: Jan. 22, 2026

(54) IMAGE SENSING DEVICE AND METHOD FOR MANUFACTURING SAME

(71) Applicant: SK hynix Inc., Icheon-si (KR)

(72) Inventor: Dong Ha KIM, Icheon-si (KR)

(21) Appl. No.: 18/945,400

(22) Filed: Nov. 12, 2024

(30) Foreign Application Priority Data
Jul. 16, 2024 (KR) 10-2024-0093458

(51) Int. Cl. H10F 39/00

(52) U.S. Cl. CPC H10F 39/8053; H10F 39/024; H10F 39/8023

(57) ABSTRACT

Image sensing devices and method for manufacturing image sensing devices are disclosed. In an embodiment, an image sensing device includes: a plurality of pixel regions and a plurality of non-pixel regions; a plurality of photodetectors disposed in the plurality of pixel regions; a plurality of trench isolation portions, each of which is disposed between adjacent photodetectors of the plurality of photodetectors in the plurality of non-pixel regions; an anti-reflection layer disposed on the plurality of photodetectors and the plurality of trench isolation portions; a first grid portion disposed on the anti-reflection layer disposed on each of the plurality of trench isolation portions in each of the plurality of non-pixel regions; a planarization layer disposed on the first grid portion in the plurality of non-pixel regions and the anti-reflection layer in the plurality of pixel regions; and a color filter on the planarization layer, wherein the first grid portion includes air.

### CROSS REFERENCE TO RELATED APPLICATION

This patent document claims the priority and benefits of Korean Patent Application No. 10-2024-0093458, filed Jul. 16, 2024, which is incorporated by reference in its entirety as part of the disclosure of this patent document.

### TECHNICAL FIELD

Various embodiments of the disclosed technology relate to image sensing devices and methods for manufacturing the same.

### BACKGROUND

With the development of the information and communication technologies and the digitalization of image information, image sensors are being used in various electrical devices, such as digital cameras, camcorders, mobile phones, personal communication systems (PCSs), game machines, surveillance and security cameras and medical micro cameras. In general, an image sensor may include a pixel region that includes photodiodes and a peripheral circuit region. A unit pixel may include a photodiode and a transfer transistor. The transfer transistor may be disposed between a photodiode and a floating diffusion region to transfer the charge generated by the photodiode to the floating diffusion region.

### SUMMARY

The disclosed technology can be implemented in some embodiments to provide an image sensing device with an improved color mixing issue of the light between neighboring pixel regions.

The disclosed technology can be implemented in some embodiments to provide an image sensing device with an improved signal-to-noise-ratio (SNR).

The disclosed technology can be implemented in some embodiments to provide an image sensing device capable of easily planarizing a color filter.

In an embodiment, an image sensing device may include a circuitry region that includes a plurality of pixel regions and a plurality of non-pixel regions, each of the plurality of non-pixel regions disposed between adjacent pixel regions of the plurality of pixel regions; a plurality of photodetectors (e.g., photodiodes) disposed in the plurality of pixel regions; a plurality of trench isolation portions disposed in the plurality of non-pixel regions, each of plurality of trench isolation portions disposed between adjacent photodetectors of the plurality of photodetectors; an anti-reflection layer disposed on the plurality of photodetectors in the plurality of pixel regions and on the plurality of trench isolation portions in the plurality of non-pixel regions; a first grid portion disposed on the anti-reflection layer disposed on each of the plurality of trench isolation portions in each of the plurality of non-pixel regions; a planarization layer disposed on the first grid portion in the plurality of non-pixel regions and the anti-reflection layer in the plurality of pixel regions; and a color filter on the planarization layer, wherein the first grid portion may include air.

In another embodiment, a method for manufacturing an image sensing device may include forming a photodetectors (e.g., photodiode) on a circuitry region that includes a plurality of pixel regions and a plurality of non-pixel regions, each of the plurality of non-pixel regions disposed between adjacent pixel regions of the plurality of pixel regions; forming a plurality of trench isolation portions disposed in the plurality of non-pixel regions, each of plurality of trench isolation portions disposed between adjacent photodetectors of the plurality of photodetectors; forming an anti-reflection layer on the plurality of photodetectors; forming a carbon layer and a stopper layer on the anti-reflection layer; etching the carbon layer and the stopper layer except the plurality of non-pixel regions; forming a first insulation layer on the etched carbon layer and the etched stopper layer; and oxidizing the carbon layer and forming a first grid portion in the plurality of non-pixel regions.

In some embodiments, a planarization layer may be disposed between an anti-reflection layer and a color filter, and a first grid portion may be disposed between the planarization layer and the anti-reflection layer in the plurality of non-pixel regions. The first grid portion may include air. That is, the first grid portion may have a structure embedded in the planarization layer. When the first grid portion has a structure embedded in the planarization layer, color mixing of the light between neighboring pixels may occur as a volume of a color filter of each pixel is reduced. For example, as a volume of a first color filter in a first pixel region is reduced, a second light beam and a third light beam, as well as a first light beam, may pass through the color filter. However, the image sensing device based on some embodiments can address these issues by embedding the first grid portion in the planarization layer, preventing color mixing of light between neighboring pixels by securing a volume of the color filter sufficiently.

In some embodiments, a second grid portion may be disposed between the planarization layer and the color filter in the plurality of non-pixel regions. The second grid portion may include a metal material. A thickness of the second grid portion may be smaller than a thickness of the first grid portion, and a width of the second grid portion may be smaller than a width of the first grid portion. That is, compared to the first grid portion embedded in the color filter, if the second grid portion is embedded in the color filter, a sufficient volume of the color filter can be secured.

In addition, in some embodiments, color mixing of light between neighboring pixels can be reduced or minimized by overlapping the first grid portion and the second grid portion.

In addition, in some embodiments, the planarization of the color filter is facilitated by embedding, in the color filter, the second grid portion having a smaller thickness.

In addition, in some embodiments, defects such as the first grid portion bursting during a high-temperature operation of the image sensing device can be prevented, by including an inorganic insulation material in the planarization layer.

### BRIEF DESCRIPTION OF THE DRAWINGS

FIG. 1 is a block diagram illustrating an imaging system based on an embodiment of the disclosed technology.

FIG. 2 is a block diagram illustrating an example of an image sensing device illustrated in FIG. 1.

FIG. 3 is a plan view illustrating an example of a pixel array illustrated in FIG. 2.

FIG. 4 is a cross-sectional view taken along line A-A′ of FIG. 3.

FIGS. 5 and 6 are cross-sectional views of a pixel array of an image sensing device implemented based on a comparative example.

FIGS. 7 to 17 are cross-sectional views illustrating various operations of a method for manufacturing an image sensing device based on an embodiment of the disclosed technology.

FIG. 18 is a cross-sectional view of a pixel array of an image sensing device based on another embodiment of the disclosed technology.

FIG. 19 is a plan view illustrating an example of a pixel array of an image sensing device based on another embodiment of the disclosed technology.

FIG. 20 is a cross-sectional view taken along line B-B′ of FIG. 19.

FIG. 21 is a cross-sectional view of a pixel array of an image sensing device based on another embodiment of the disclosed technology.

FIG. 22 is a plan view illustrating an example of a pixel array of an image sensing device based on another embodiment of the disclosed technology.

FIG. 23 is a cross-sectional view taken along line C-C′ of FIG. 22.

FIG. 24 is a cross-sectional view of a pixel array of an image sensing device based on another embodiment of the disclosed technology.

FIG. 25 is a plan view illustrating an example of a pixel array of an image sensing device based on another embodiment of the disclosed technology.

FIG. 26 is a plan view illustrating an example of a pixel array of an image sensing device based on another embodiment of the disclosed technology.

FIG. 27 is a plan view illustrating an example of a pixel array of an image sensing device based on another embodiment of the disclosed technology.

FIG. 28 is a plan view illustrating an example of a pixel array of an image sensing device based on another embodiment of the disclosed technology.

FIG. 29 is a plan view illustrating an example of a pixel array of an image sensing device based on another embodiment of the disclosed technology.

FIG. 30 is a plan view illustrating an example of a pixel array of an image sensing device based on another embodiment of the disclosed technology.

FIG. 31 is a plan view illustrating an example of a pixel array of an image sensing device based on another embodiment of the disclosed technology.

### DETAILED DESCRIPTION

Hereinafter, example embodiments will be described with reference to the accompanying drawings.

Like reference numerals refer to like elements throughout. Additionally, in the drawings, the thicknesses, proportions, and dimensions of components may be exaggerated for the purpose of effective explanation.

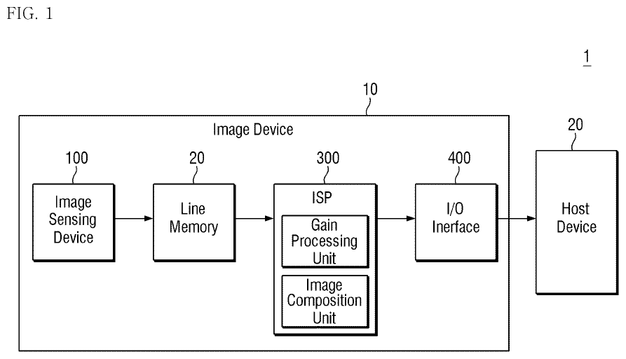

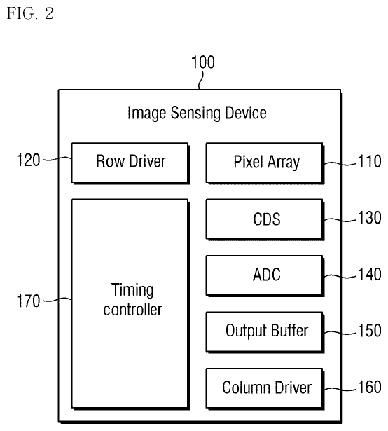

FIG. 1 is a block diagram illustrating an imaging system based on an embodiment of the disclosed technology. FIG. 2 is a block diagram illustrating an example of an image sensing device illustrated in FIG. 1.

Referring to FIG. 1, in some embodiments, the imaging system 1 may refer to a device such as a digital still camera for capturing still images, a digital video camera for recording videos, or a device for detecting motion. For example, the imaging device 10 may be implemented as a Digital Single Lens Reflex (DSLR) camera, a mirrorless camera, or a smartphone, and others, but is not limited thereto. The imaging device 10 may include a device including a lens and an image sensor to capture a target object and create an image of the target object.

The imaging system 1 may include an imaging device 10 and a host device 20.

The imaging device 10 may include an image sensing device 100, a line memory 200, an image signal processor (ISP) 300, and an input/output (I/O) interface 400.

The image sensing device 100 may be a complementary metal oxide semiconductor image sensor (CMOS image sensor or CIS) for converting an optical signal into an electrical signal. The image sensing device 100 may control overall operations such as on/off operations, operation mode, operation timing, sensitivity, etc. by the ISP 300. The image sensing device 100 may transmit, to the line memory 200, with image data obtained by converting the optical signal into the electrical signal under control of the ISP 300.

Referring to FIG. 2, the image sensing device 100 may include a pixel array 110, a row driver 120, a correlated double sampler (CDS) 130, an analog-digital converter (ADC) 140, an output buffer 150, a column driver 160, and a timing controller 170. The components of the image sensing device 100 illustrated in FIG. 2 are discussed by way of example only, and at least some components may be added or omitted as needed.

The pixel array 110 may include a plurality of imaging pixels arranged in a plurality of rows and a plurality of columns. In an embodiment, the plurality of imaging pixels can be arranged in a two dimensional pixel array including rows and columns. In another example, the plurality of imaging pixels can be arranged in a three dimensional pixel array. The plurality of imaging pixels may convert an optical signal into an electrical signal on a unit pixel basis or a pixel group basis, where the imaging pixels in a pixel group share at least certain internal circuitry. The pixel array 110 may receive pixel control signals, including a row selection signal, a pixel reset signal and a transmission signal, from the row driver 120. Upon receiving the pixel control signals, corresponding pixels in the pixel array 110 may be activated to perform the operations corresponding to the row selection signal, the pixel reset signal, and the transmission signal. Each of the imaging pixels may generate photocharges corresponding to the intensity of incident light (or luminous intensity), may generate an electrical signal corresponding to the amount of photocharges, thereby sensing the incident light. For convenience of description, the imaging pixel may also be referred to as a pixel.

The row driver 120 may activate the pixel array 110 to perform certain operations on the imaging pixels in the corresponding row based on commands and control signals provided by the timing controller 170. In an embodiment, the row driver 120 may select at least one pixel arranged in at least one row of the pixel array 110. The row driver 120 may generate a row selection signal to select at least one row among the plurality of rows. The row driver 120 may sequentially enable the pixel reset signal and the transmission signal for the pixels corresponding to at least one selected row. Thus, a reference signal and an image signal, which are analog signals generated by each of the pixels of the selected row, may be sequentially transferred to the CDS 130. The reference signal may be an electrical signal that is provided to the CDS 130 when a sensing node of a pixel (e.g., floating diffusion node) is reset, and the image signal may be an electrical signal that is provided to the CDS 130 when photocharges generated by the imaging pixel are accumulated in the sensing node. The reference signal indicating unique reset noise of each pixel and the image signal indicating the intensity of incident light may be referred to as a pixel signal.

The image sensing device 100 may use the correlated double sampling (CDS) to remove undesired offset values of pixels known as the fixed pattern noise by sampling a pixel signal twice to remove the difference between these two samples. In an embodiment, the correlated double sampling (CDS) may remove the undesired offset value of pixels by comparing pixel output voltages obtained before and after photocharges generated by incident light are accumulated in the sensing node so that only pixel output voltages based on the incident light can be measured. In some embodiments of the disclosed technology, the CDS 130 may sequentially sample and hold voltage levels of the reference signal and the image signal, which are provided to each of a plurality of column lines from the pixel array 110. That is, the CDS 130 may sample and hold the voltage levels of the reference signal and the image signal which correspond to each of the columns of the pixel array 110.

The CDS 130 may transfer the reference signal and the image signal of each of the columns as a correlate double sampling signal to the ADC 140 based on control signals from the timing controller 170.

The ADC 140 may convert analog CDS signals output from the CDS 130 with respect to each column into digital signals, and output image data. In an embodiment, the ADC 140 may convert the correlate double sampling signal generated by the CDS 130 for each of the columns into a digital signal, and output the digital signal.

The ADC 140 may include a plurality of column counters. Each column of the pixel array 110 is coupled to a column counter, and image data can be generated by converting the correlate double sampling signals corresponding to each column into digital signals using the column counter. In another embodiment of the disclosed technology, the ADC 140 may include a global counter to convert the correlate double sampling signals corresponding to each of the columns into digital signals using a global code provided from the global counter.

The output buffer 150 may temporarily hold the column-based image data provided from the ADC 140 to output the image data. The output buffer 150 may temporarily store image data output from the ADC 140 based on the control signal of the timing controller 170. The output buffer 150 may serve as an interface to compensate for data rate differences (or data processing speed differences) between the image sensing device 100 and other devices.

The column driver 160 may select a column of the output buffer 150 based on a control signal from the timing controller 170, and sequentially output the image data, which are temporarily stored in the selected column of the output buffer 150. In an embodiment, the column driver 160 may receive an address signal from the timing controller 170, generate a column selection signal based on the address signal and select a column of the output buffer 150, thereby outputting the image data from the selected column of the output buffer 150.

The timing controller 170 may control at least one among the row driver 120, the CDS 130, the ADC 140, the output buffer 150 and the column driver 160.

The timing controller 170 may provide at least one among the row driver 120, the CDS 130, the ADC 140, the output buffer 150 and the column driver 160 with a clock signal required for the operations of the respective components of the image sensing device 100, a control signal for timing control, and address signals for selecting a row or column. In an embodiment of the disclosed technology, the timing controller 170 may include a logic control circuit, a phase lock loop (PLL) circuit, a timing control circuit, a communication interface circuit and others.

Referring back to FIG. 1, the line memory 200 may include a volatile memory (e.g., DRAM, SRAM, etc.) and/or a non-volatile memory (e.g., a flash memory). The line memory 200 may have a capacity capable of storing image data corresponding to a predetermined number of lines. In this case, the line may refer to a row of the pixel array 110, and the predetermined number of lines may be less than a total number of rows of the pixel array 120. Therefore, the line memory 200 may be a line memory capable of storing image data corresponding to some rows (or some lines) of the pixel array 110, rather than a frame memory capable of storing image data corresponding to a frame captured once by the pixel array 110. In another embodiment, the line memory 200 may also be replaced with a frame memory.

The line memory 200 may receive image data from the image sensing device 100, may store the received image data, and may transmit the stored image data to the ISP 300 based on the control of the ISP 300.

The ISP 300 may perform image processing of the image data stored in the line memory 200. The ISP 300 may reduce noise of image data, and may perform various kinds of image signal processing such as gamma correction, color filter array interpolation, color matrix, color correction, color enhancement, lens distortion correction, etc. for image-quality improvement of the image data. In addition, the ISP 300 may compress image data that has been created by execution of image signal processing for image-quality improvement, such that the ISP 300 can create an image file using the compressed image data. Alternatively, the ISP 300 may recover image data from the image file. In this case, the scheme for compressing such image data may be a reversible format or an irreversible format. As a representative example of such compression format, in the case of using a still image, Joint Photographic Experts Group (JPEG) format, JPEG 2000 format, or the like can be used. In addition, in the case of using moving images, a plurality of frames can be compressed according to Moving Picture Experts Group (MPEG) standards such that moving image files can be created. For example, the image files may be created according to Exchangeable image file format (Exif) standards.

In order to generate the HDR image, the ISP 300 may include a gain processing unit 310, and an image composition unit 320.

The gain processing unit 310 may determine a gain to be calculated with (to be multiplied by) image data. The gain processing unit 310 may determine a gain according to a difference in the conversion gain between the high conversion gain (HCG) mode and the low conversion gain (LCG) mode, and may provide the determined gain to the image composition unit 320. The gain may be experimentally determined in advance according to the difference in the conversion gain, and may be stored in the gain processing unit 310. In an embodiment, the gain processing unit 310 may store the experimentally determined gain in a table according to a size of the image data, such that the gain processing unit 310 may acquire a necessary gain corresponding to the image data by referring to content stored in the table.

Each pixel of the pixel array 110 may operate in one mode among the HCG mode and LCG mode, and the mode of each pixel may be determined according to the intensity (or illuminance) of the light incident on each pixel. The HCG mode means a mode in which the pixel has a relatively greater conversion gain, and the LCG mode means a mode in which the pixel has relatively smaller conversion gain. Here, the conversion gain may mean a ratio of a voltage level of the pixel signal, of which the photocharges are converted, to the amount of photocharges generated in the pixel. The amount of photocharges generated in the pixel is proportionate to illuminance with respect to each pixel, and thus, the HCG mode may mean a mode having a relatively greater change of the pixel signal according to the change of the illuminance, and the LCG mode may mean a mode having a relatively smaller change of the pixel signal according to the change of the illuminance.

That is, in the HCG mode and the LCG mode, slopes of the pixel signal with respect to the illuminance are different from each other. The gain may be a correction value to make a slope of the pixel signal (or image data) with respect to the illuminance of the pixel operating in the HCG mode, and a slope of the pixel signal (or image data) with respect to the illuminance of the pixel operating in the LCG mode be equal to each other.

The image composition unit 320 may synthesize HDR image corresponding to a high dynamic range by using the image data of the pixel operating in the HCG mode and/or the image data of the pixel operating in the LCG mode.

In an embodiment, the image composition unit 320 may may perform a calculation, using the gain provided from the gain processing unit 310, on the image data of the pixel operating in the HCG mode and/or the image data of the other pixel operating in the LCG mode, and may allow the calculated image data to be formed as the HDR image.

The ISP 300 may transmit image data (e.g., HDR image data) obtained by such image signal processing to the I/O interface 400.

In another embodiment, the gain processing unit 310 and the image composition unit 320 that are used to generate the HDR image may also be included in the image sensing device 100, not in the ISP 300.

The I/O interface 400 may perform a communication with the host device 20, and may transmit the image signal processed (ISP) image data to the host device 20. In an embodiment, the I/O interface 400 may be implemented as, for example, a mobile industry processor interface (MIPI), but the range is not limited thereto.

The host device 20 may be a processor (e.g., an application processor) for processing the ISP image data received from the imaging device 10, a memory (e.g., a non-volatile memory) for storing the ISP image data, or a display device (e.g., a liquid crystal display (LCD)) for visually displaying the ISP image data.

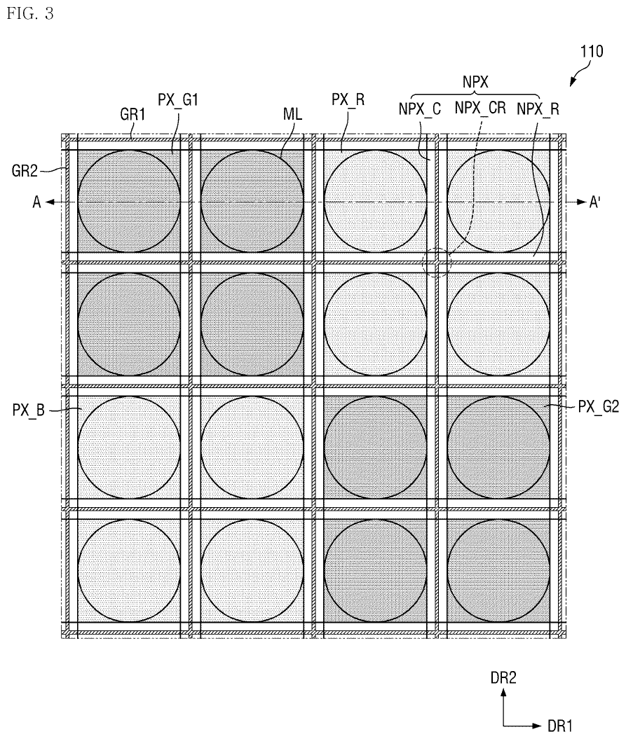

FIG. 3 is a plan view illustrating an example of a pixel array illustrated in FIG. 2.

Referring to FIG. 3, the pixel array 110 based on an embodiment may include a plurality of pixels. The plurality of pixels may include a first pixel, a second pixel, a third pixel, and a fourth pixel. Each pixel may include pixel regions PX_R, PX_G1, PX_G2, and PX_B, and a non-pixel region NPX. The first pixel may be a green pixel which receives green light, the second pixel may be a red pixel which receives red light, the third pixel may be a blue pixel which receives blue light, and the fourth pixel may be a green pixel which receives green light. During the daytime, each pixel may receive light in the wavelength range of a visible ray in correspondence with the wavelength range. For example, the first pixel, the second pixel, the third pixel, and the fourth pixel may further receive light in the wavelength range of the infrared light. That is, peak wavelengths of the first pixel and the fourth pixel may be a green wavelength and an infrared wavelength, peak wavelengths of the second pixel may be a red wavelength and the infrared wavelength, and peak wavelengths of the third pixel may be a blue wavelength and the infrared wavelength. That is, during the daytime, there is little light within the wavelength range of the visible ray, and therefore, each pixel may receive light within the infrared wavelength range per region. The plurality of pixels may be repeatedly disposed along a first direction DR1 and a second direction DR2, but are not limited thereto. Considering a peak wavelength range of the light to be received, a color filter may be disposed in each of the plurality of pixels. For example, a green color filter is disposed in the first pixel and the fourth pixel, a red color filter is disposed in the second pixel, and a blue color filter is disposed in the third pixel.

In some embodiments, the plurality of pixels may further include a fifth pixel which receives white light, but the disclosed technology is not limited thereto.

The first pixel includes a first pixel region PX_G1 and a non-pixel region NPX disposed between adjacent pixel regions, for example, surrounding the first pixel region PX_G1, a second pixel includes a second pixel region PX_GR and a non-pixel region NPX disposed between adjacent pixel regions, for example, surrounding the second pixel region PX_GR, a third pixel includes a third pixel region PX_B and a non-pixel region NPX disposed between adjacent pixel regions, for example, surrounding the third pixel region PX_B, and a fourth pixel includes a fourth pixel region PX_G2 and a non-pixel region NPX disposed between adjacent pixel regions, for example, surrounding the fourth pixel region PX_G2. Each of the pixels may be formed by grouping multiple pixels together. For example, four pixels may be grouped and arranged together. For example, the first pixel, the second pixel, the third pixel, and the fourth pixel may be grouped and arranged in sets of four, as illustrated in FIG. 3. For example, pixels may be arranged in a two-by-two array configuration, but the disclosed technology not limited thereto.

For example, the grouped first pixels may be arranged in pairs along a row direction (or a first direction DR1) and a column direction (or a second direction DR2), the grouped second pixels may be arranged in pairs along the row direction (or the first direction DR1) and the column direction (or the second direction DR2), the grouped third pixels may be arranged in pairs along the row direction (or the first direction DR1) and the column direction (or the second direction DR2), and the grouped fourth pixels may be arranged in pairs along the row direction (or the first direction DR1) and the column direction (or the second direction DR2. The grouped first pixels, the grouped second pixels, the grouped third pixels, and the grouped fourth pixels may be disposed in a matrix configuration. That is, the grouped first pixels, the grouped second pixels, the grouped third pixels, and the grouped fourth pixels may be disposed along the row direction (or the first direction DR1) and the column direction (or the second direction DR2) in a matrix configuration.

The non-pixel region NPX may be formed between neighboring pixels. For example, the non-pixel region NPX may be disposed in boundaries between the grouped first pixels, the grouped second pixels, the grouped third pixels, and the grouped fourth pixels, and in boundaries between the grouped first pixels, between the grouped second pixels, between the grouped third pixels, and between the grouped fourth pixels.

For example, the non-pixel region NPX may include a first non-pixel region NPX_R extending along the row direction (or the first direction DR1), a second non-pixel region NPX_C extending along the column direction (or the second direction DR2), and a third non-pixel region NPX_CR extending in a boundary between the first non-pixel region NPX_R and the second non-pixel region NPX_C.

The first non-pixel region NPX_R may extend along a boundary between the grouped first pixels and the grouped third pixels and a boundary between the grouped second pixels and the grouped fourth pixels, and along an internal boundary (a boundary extending along the first direction DR1) of each of the grouped first pixels, the grouped second pixels, the grouped third pixels, and the grouped fourth pixels.

The second non-pixel region NPX_C may extend along a boundary between the grouped first pixels and the grouped third pixels and a boundary between the grouped second pixels and the grouped fourth pixels, and along an internal boundary (a boundary extending along the second direction DR2) of each of the grouped first pixels, the grouped second pixels, the grouped third pixels, and the grouped fourth pixels.

The pixel array 110 based on an embodiment may further include a light concentrating pattern ML. In some implementations, a plurality of light concentrating patterns ML may be disposed. For example, the plurality of light concentrating patterns ML may be disposed in each of the pixels. That is, the plurality of light concentrating patterns ML may be disposed in each of the grouped first pixels, may be disposed in each of the grouped second pixels, may be disposed in each of the grouped third pixels, and may be disposed in each of the grouped fourth pixels, but the disclosed technology is not limited thereto. That is, the plurality of light concentrating patterns ML may be disposed in each pixel region of the grouped pixels. In FIG. 3, sixteen pixel regions are illustrated, and sixteen light concentrating patterns ML may be disposed. In some embodiments, the pixel array 110 may include a meta lens layer, instead of the light concentrating patterns ML. The meta lens layer may serve to receive light incident from the outside into the pixel regions PX_R, PX_G1, PX_B, and PX_G2.

The pixel array 110 based on an embodiment may further include a grid portion. The grid portion may include a first grid portion GR1 and a second grid portion GR2. The first grid portion GR1 may include an air structure (e.g., a structure that includes air), and the second grid portion GR2 may include a metal material. For example, the second grid portion GR2 may include a metal material which absorbs light, and may include tungsten (W), but the disclosed technology is not limited thereto.

For example, the first grid portion GR1 may be disposed throughout the first non-pixel region NPX_R and the second non-pixel region NPX_C of the non-pixel region NPX, and the first grid portion GR1 may not disposed over the third non-pixel region NPX_CR. However, the disclosed technology is not limited thereto, and the first grid portion GR1 may be disposed over the third non-pixel region NPX_CR.

The second grid portion GR2 may be disposed throughout the first non-pixel region NPX_R, the second non-pixel region NPX_C, and the third non-pixel region NPX_CR of the non-pixel region NPX.

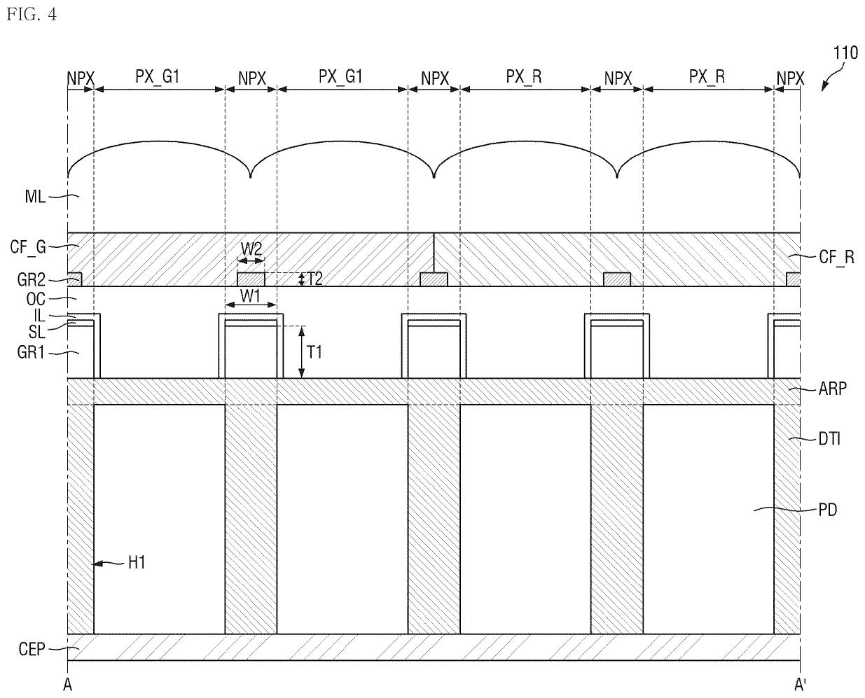

FIG. 4 is a cross-sectional view taken along line A-A′ of FIG. 3. In FIG. 4, a cross-sectional view of the pixel array of the first pixel and the second pixel is illustrated. In FIG. 4, two first pixels among the grouped first pixels and two second pixels among the grouped second pixels are illustrated.

Referring to FIG. 4, the pixel array 110 based on an embodiment includes a circuitry region CEP, a photosensing device or photodetector such as a photodiode PD on the circuitry region CEP, a first trench isolation portion DTI disposed between adjacent photodiodes PDs, an anti-reflection layer ARP on the photodiode PD, a first grid portion GR1 on the anti-reflection layer ARP in the non-pixel region NPX, a stopper layer SL on the first grid portion GR1 in the non-pixel region NPX, an insulation layer IL on the stopper layer SL and the anti-reflection layer ARP, a planarization layer OC on the insulation layer IL, a second grid portion GR2 on the planarization layer OC in the non-pixel region NPX, color filters CF_G and CF_R on the second grid portion GR2 and the planarization layer OC, the light concentrating pattern ML on the color filters CF_G and CF_R.

The circuitry region CEP is disposed on a bottom surface of the photodiode PD, and may include transistors, a wiring layer, and an interlayer insulation layer. The transistors may include an overflow transistor, a transfer transistor, a reset transistor, a driving transistor, and a selection transistor, all of which are formed on the bottom surface of the photodiode PD.

The photodiode PD may include a single-crystalline silicon wafer or an epitaxially grown single-crystalline silicon layer. The photodiode PD may have a high refractive index. For example, the refractive index of the photodiode PD may be about 2.5 or more, but is not limited thereto. For example, the refractive index of the photodiode PD may be about 4 to 6, but is not limited thereto.

The photodiode PD may be formed by injecting P-type ions and N-type ions. The P-type ions may include boron (B) ions, and N-type ions may include phosphorous (P) ions and/or arsenic (As) ions. The photodiode PD serves to convert the optical signals into the electric signals by receiving the incident light. The photodiode PD may refer to only a portion which corresponds to the pixel regions PX_R and PX_G1, but is not limited thereto.

In some implementations, a first groove H1 may be formed in the photodiode PD. The first groove H1 may be formed by indenting the photodiode PD in a thickness direction. The first groove H1 may be formed in the non-pixel region NPX. For example, the first groove H1 may completely pass through the photodiode PD from an upper surface to a bottom surface thereof. In some implementations, the first trench isolation portion DTI may be formed in the first groove H1. The first trench isolation portion DT1 may be formed through a deep trench process. The first trench isolation portion DT1 may fill the first groove H1. In some embodiments, a second groove may be formed in the photodiode PD. For example, one or two second grooves, or three or more second grooves may be formed in the pixel regions PX_G1 and PX_R. In some implementations, a second trench isolation portion may be disposed in the second groove. For example, one or two second trench isolation portions, or three or more second trench isolation portions may be disposed in one pixel region PX_G1 and PX_R. The first trench isolation portion DTI and the second trench isolation portion may include the same material. For example, the first trench isolation portion DTI and the second trench isolation portion may include an insulation material which provides some level of electrical insulation between two adjacent photodiodes. Examples of the insulation material may include hafnium oxide (HfO2), or silicon oxide (SiO₂), but is not limited thereto. The refractive index of the first trench isolation portion DTI may be, for example, about 1.4 to 2.0, but is not limited thereto. In addition to provide insulation between adjacent photodiodes, the first trench isolation portion DTI serves to totally reflect light incident on the first trench isolation portion DTI to the photodiode PD. The second trench isolation portion serves to scatter light incident from the light concentrating pattern MLP. The first trench isolation portion DTI and the second trench isolation portion may serve to increase a path of the light by totally reflecting the light to the photodiode PD or scattering the light. As a result, the trench isolation portion may serve to improve a quantum efficiency of the photodiode PD. In some embodiments, the first trench isolation portion DTI may be designed to include polysilicon (Poly Si), and the above mentioned insulation material formed on a side wall of the polysilicon, but the disclosed technology is not limited thereto.

The anti-reflection layer ARP may be disposed on the photodiode PD and the trench isolation portion DTI. The anti-reflection layer ARP may be in direct contact with the photodiode PD and the first trench isolation portion DTI. The anti-reflection layer ARP may include a material which is the same as the material of the first trench isolation portion DTI. The anti-reflection layer ARP may be formed in the same manufacture process as the manufacture process of the first trench isolation portion DTI, and may be integrally connected with the first trench isolation portion DTI. The anti-reflection layer ARP may serve to prevent the light incident on the light concentrating pattern MLP from being totally reflected in the photodiode PD. To this end, the anti-reflection layer ARP may have a refractive index between a refractive index of the color filters CF_G and CF_R and a refractive index of the photodiode PD, but is not limited thereto. For example, the refractive index of the anti-reflection layer ARP may be about 1.4 to 2.0, but is not limited thereto. The anti-reflection layer ARP may be disposed throughout the pixel regions PX_R and PX_G1, and the non-pixel region NPX.

The first grid portion GR1 may be disposed on the anti-reflection layer ARP. The first grid portion GR1 may be disposed in the non-pixel region NPX. The first grid portion GR1 may include a low refractive layer. For example, the first grid portion GR1 may include a low refractive insulation material, or an air structure. In an embodiment, the first grid portion GR1 may include an air structure (e.g., a structure that includes air). The first grid portion GR1 may be disposed in the non-pixel region NPX, and may serve to totally reflect the light incident on the first grid portion GR1. The first grid portion GR1 may prevent color mixing of the light between the neighboring pixel regions PX_R and PX_G1. A thickness T1 of the first grid portion GR1 may be greater than a thickness T2 of the second grid portion GR2 which will be described below, and a width W1 of the first grid portion GR1 may be greater than a width W2 of the second grid portion GR2, as will be described below, but the disclosed technology is not limited thereto. The second grid portion GR2 which will be described below may include a metal. The second grid portion GR2 is disposed in the non-pixel region NPX, thereby absorbing light incident on the second grid portion GR2. The second grid portion GR2 may prevent color mixing of light between the neighboring pixel regions PX_R and PX_G1. Each of the first grid portion GR1 and the second grid portion GR2 may be disposed in a boundary between the grouped first pixels, a boundary between the grouped second pixels, and a boundary between the first pixel and the second pixel, but the disclosed technology is not limited thereto.

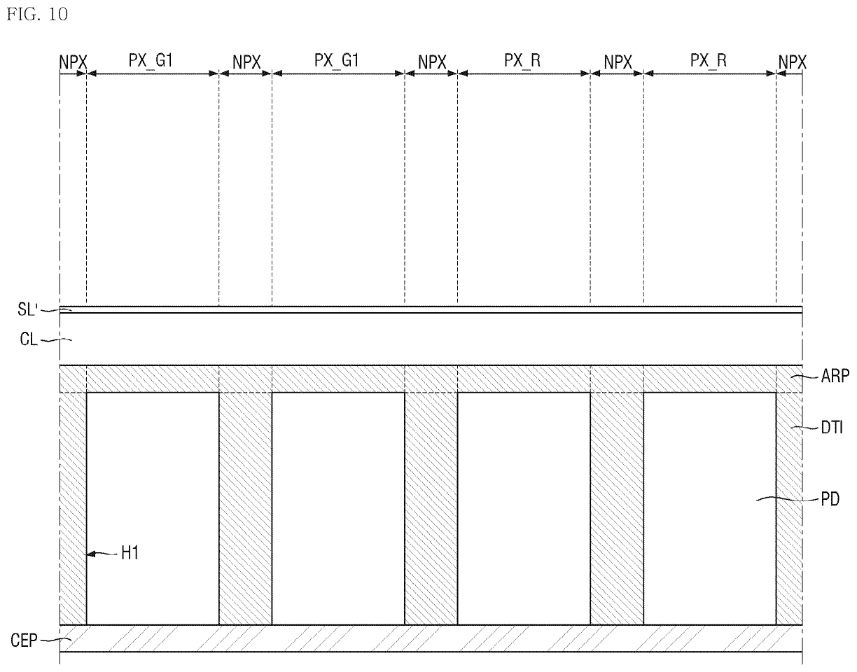

On the first grid portion GR1 in the non-pixel region NPX, the stopper layer SL may be disposed. The stopper layer SL is disposed on a carbon layer (refer to CL in FIG. 10) which will be described below and may serve as an etching stopper with respect to an etchant or an etching gas in the course of removing the carbon layer (refer to CL in FIG. 10) in the pixel regions PX_G1 and PX_R. For example, the stopper layer SL may include silicon nitride (SiNx), but the disclosed technology is not limited thereto.

The insulation layer IL may be disposed on the stopper layer SL and the first grid portion GR1. The insulation layer IL may include an insulation material. For example, the insulation layer IL may include silicon oxide (SiO₂), but is not limited thereto. The insulation layer IL may directly contact a side surface of the first grid portion GR1, a side surface of the stopper layer SL, and an upper surface of the stopper layer SL. The insulation layer IL may expose an upper surface of the anti-reflection layer ARP in the pixel regions PX_G1 and PX_R. However, the disclosed technology is not limited thereto, the insulation layer IL may entirely cover the upper surface of the anti-reflection layer ARP in the pixel regions PX_G1 and PX_R. The insulation layer IL is formed in a region in which the first grid portion GR1 is to be formed in a process of forming the first grid portion GR1 including the air structure. Oxygen is irradiated onto the insulation layer IL, and the irradiated oxygen passes through the insulation layer IL and oxidizes the carbon layer filling the region where the first grid portion GR1 are to be formed. The oxidized carbon layer becomes carbon dioxide and is removed to form the first grid portion GR1 having the air structure. Therefore, the insulation layer IL may be a multi-porous layer.

The planarization layer OC may be disposed on the first grid portion GR1 and the anti-reflection layer ARP. The planarization layer OC may include an organic insulation material. However, the disclosed technology is not limited thereto, and the planarization layer OC may include an inorganic insulation material. The first grid portion GR1 may be embedded in the planarization layer OC. The planarization layer OC may be disposed throughout the pixel regions PX_G1 and PX_R and the non-pixel region NPX. The planarization layer OC may directly contact an upper surface of the anti-reflection layer ARP and the insulation layer IL. The planarization layer OC may be disposed between the insulation layer IL and the second grid portion GR2 in the non-pixel region NPX. However, the disclosed technology is not limited thereto, and the planarization layer OC may not be disposed between the insulation layer IL and the second grid portion GR2 in the non-pixel region NPX. That is, the first grid portion and the second grid portion may substantially meet each other.

The second grid portion GR2 may be disposed on the planarization layer OC in the non-pixel region NPX. The second grid portion GR2 may include a metal material. The second grid portion GR2 may overlap the first grid portion GR1 in a thickness direction. The features of the second grid portion GR2 are similar to what is discussed above, and thus further descriptions will be omitted here.

The color filters CF_G and CF_R may be disposed on the second grid portion GR2 and the planarization layer OC. The first color filter CF_G may receive light in a green wavelength range and an ultraviolet wavelength range, and block light in the remaining wavelength ranges. The second color filter CF_R may receive light in a red wavelength range and an ultraviolet wavelength range, and block light in the remaining wavelength ranges.

The light concentrating pattern ML may be disposed on the color filters CF_G and CF_R. The light concentrating pattern ML may serve to receive light coming from the outside onto the pixel regions PX_G1 and PX_R. To this end, the light concentrating pattern ML may have a shape of a convex lens that is convex upward, and may be formed of a material with a great difference in the refractive index compared to the refractive index of the external air. For example, the refractive index of the light concentrating pattern ML can be, but is not limited to, about 1.5 to about 1.7. The light concentrating pattern MLP may be arranged continuously in the pixel regions PX_G1 and PX_R and the non-pixel region NPX, as shown in FIG. 4, and may be formed such that an end of the convex lens shape is positioned in the center of the pixel regions PX_G1 and PX_R, but is not limited to. For example, the light concentrating pattern ML may be disconnected in the non-pixel region NPX, in which case the plurality of the light concentrating patterns ML may be positioned in each of the pixel regions PX_G1 and PX_R. For example, the light concentrating pattern ML may be disposed in each of the grouped first pixels, and in each of the grouped second pixels, but the disclosed technology is not limited thereto.

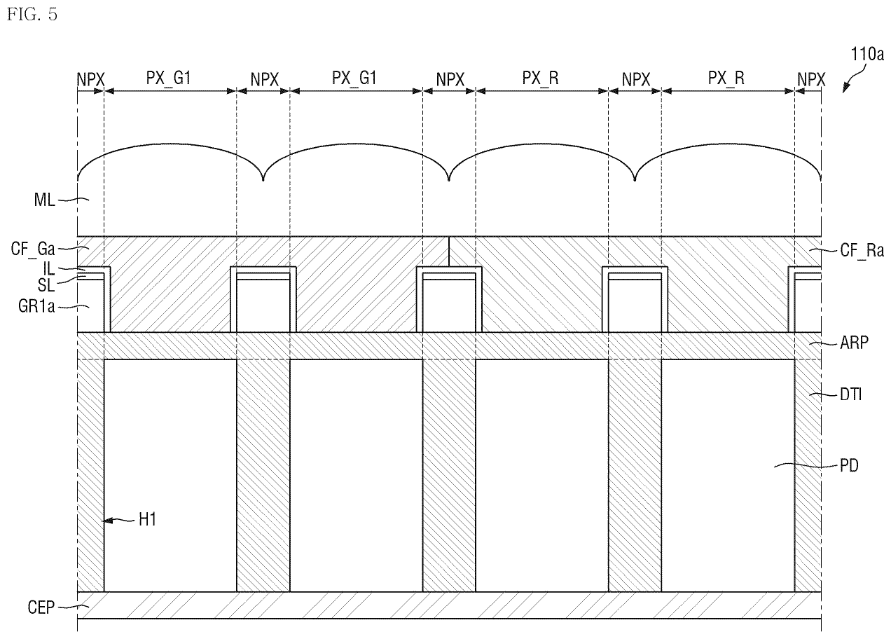

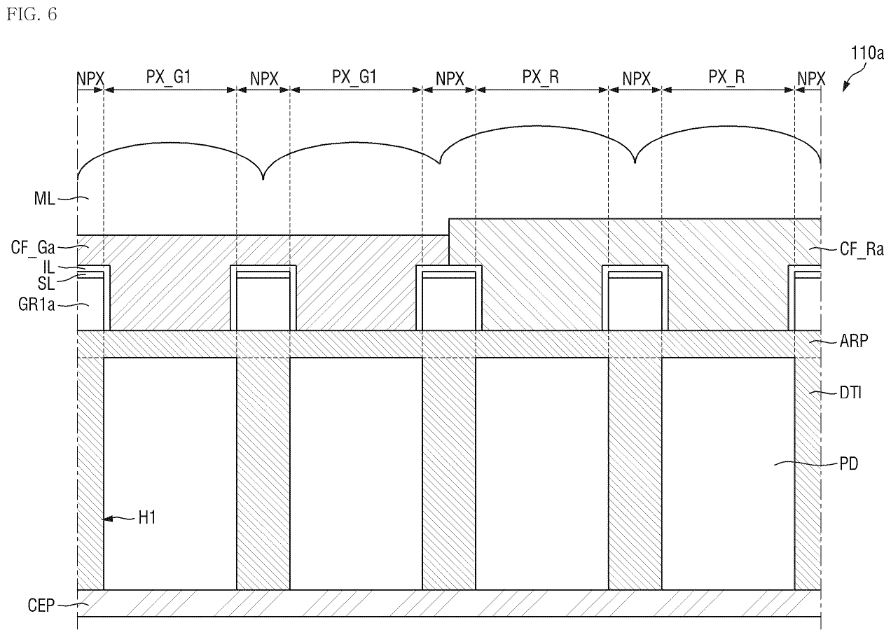

FIGS. 5 and 6 are cross-sectional views of a pixel array of an image sensing device implemented based on a comparative example.

Referring to FIGS. 4 to 6, in the pixel array 110a of the image sensing device according to the comparative embodiment, the planarization layer OC in FIG. 4 is omitted and a first grid portion GR1a is embedded in color filters CF_Ga and CF_Ra.

In FIG. 5, a surface of the color filters CF_Ga and CF_Ra is planarized, however, because the first grid portion GR1a is embedded in the color filters CF_Ga and CF_Ra, if there is some volume deviation of each of the color filters CF_Ga and CF_Ra, the surface of color filters CF_Ga and CF_Ra may be formed to be non-planar, as illustrated in FIG. 6. When the color filters CF_Ga and CF_Ra have a non-planar or uneven surface, as illustrated in FIG. 6, the light concentrating pattern MP on the color filters CF_Ga and CF_Ra may be formed to have a non-planar or uneven surface due to the non-planar or uneven surface of the color filters CF_Ga and CF_Ra. When the light concentrating pattern MP has a non-planar or uneven surface, because the focusing of light by the light concentrating pattern MP is uneven, the signal-to-noise-ratio (SNR) of the image sensing device may be lowered.

In order to improve the SNR, a process for planarizing the surface of the color filters CF_Ga and CF_Ra may be additionally performed before forming the light concentrating pattern MP, and the first grid portion GR1 may be damaged in the process for planarizing the surface of the color filters CF_Ga and CF_Ra.

In addition, the first grid portion GR1 having a greater volume (greater width and thickness) compared to that of the second grid portion GR2 is embedded in the color filters CF_Ga and CF_Ra, and the light color mixing between neighboring pixels may occur as the volume of the color filters CF_Ga and CF_Ra is reduced. For example, as the volume of the first color filter CF_Ga in the first pixel region PX_G1 is reduced, the red light and the blue light as well as the green light may pass through the first color filter CF_Ga.

However, the image sensing device illustrated in FIG. 4 can sufficiently secure the volume of the color filters CF_G and CF_R by embedding the first grid portion GR1 in the planarization layer OC, thereby preventing the light color mixing between neighboring pixels.

In addition, the second grid portion GR2 is disposed in the non-pixel region NPX between the planarization layer OC and the color filters CF_G and CF_R, and because the volume of the second grid portion GR2 is smaller than the volume of the first grid portion GR1, there is an effect that the volume of the color filters CF_G and CF_R can be sufficiently secured compared to a case where the second grid portion GR2 is embedded in the color filters CF_G and CF_R.

In addition, the light color mixing between neighboring pixels can be reduced or minimized by overlapping the first grid portion GR1 and the second grid portion GR2.

In addition, because the second grid portion GR2 having the smaller thickness is embedded in the color filters CF_G and CF_R, as illustrated in FIG. 6, the surface planarization of the color filters is facilitated even if the color filters have a non-planar surface, and degradation of the signal-to-noise-ratio (SNR) of the image sensing device can be prevented.

Hereinafter, a method for manufacturing the pixel array 110 based on an embodiment will be described. The method for manufacturing the pixel array 110 described below will omit redundant explanations for the components described above referring to FIGS. 1 to 6.

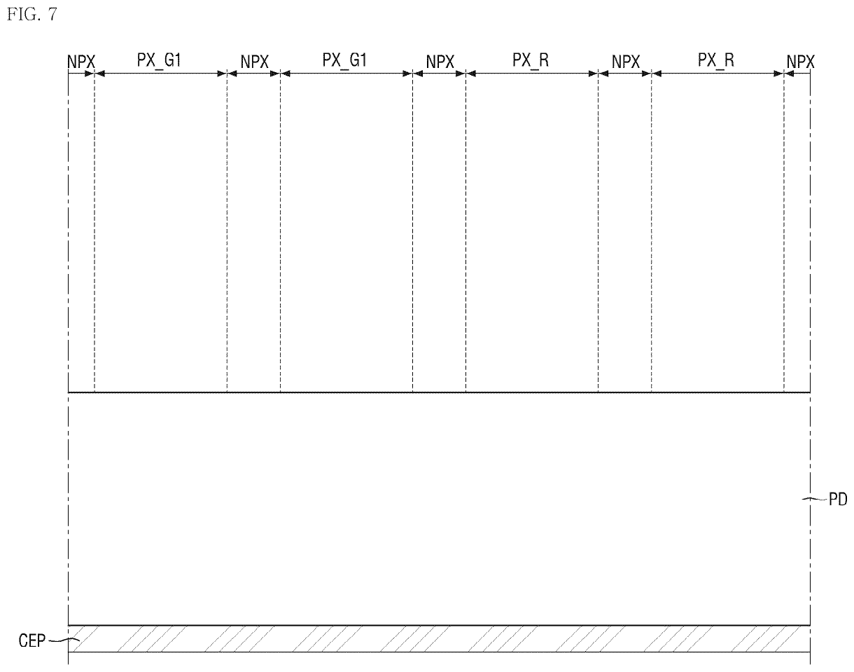

FIGS. 7 to 17 are cross-sectional views illustrating various operations of a method for manufacturing an image sensing device based on an embodiment of the disclosed technology.

Referring to FIGS. 4 to 7, the photodiode PD is disposed on the circuitry CEP. The circuitry CEP is disposed on a bottom surface of the photodiode PD, and may include transistors, a wiring layer, and an interlayer insulation layer. The transistors may include an overflow transistor, a transfer transistor, a reset transistor, a driving transistor, and a selection transistor, all of which are formed on the bottom surface of the photodiode PD. The photodiode PD may include a single-crystalline silicon wafer or an epitaxially grown single-crystalline silicon layer. The photodiode PD may have a high refractive index. For example, the refractive index of the photodiode PD may be about 2.5 or more, but is not limited thereto. For example, the refractive index of the photodiode PD may be about 4 to 6, but is not limited thereto.

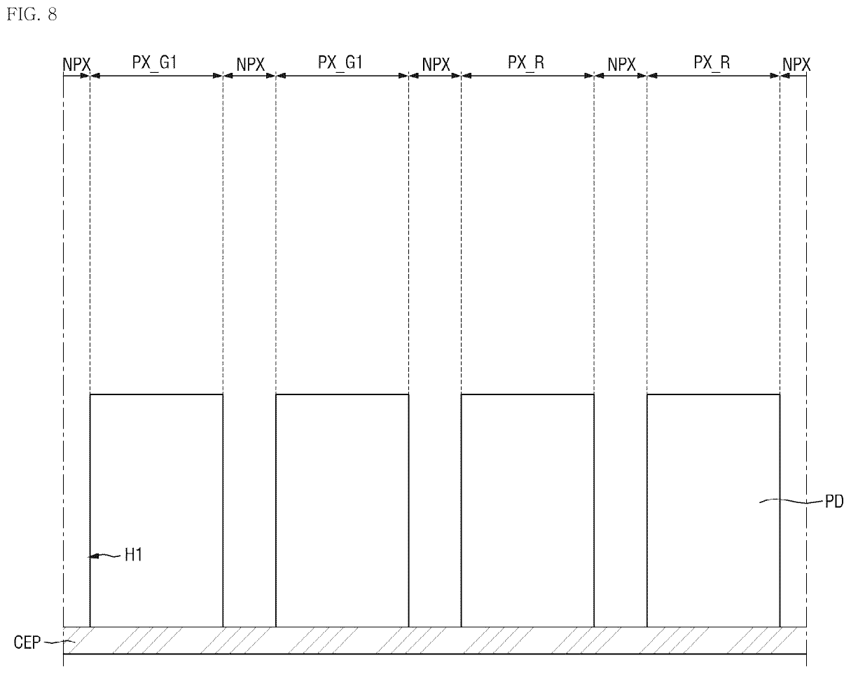

Referring to FIGS. 4 and 8, in the photodiode PD, the first groove H1 may be formed. The first groove H1 may be formed by indenting the photodiode PD in a thickness direction. The first groove H1 may be formed in the non-pixel region NPX.

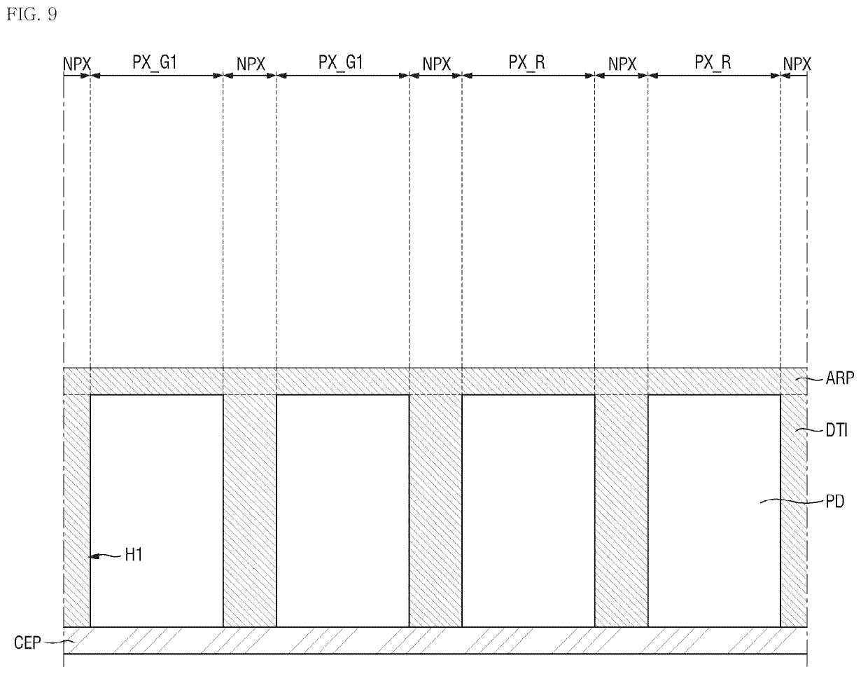

Referring to FIGS. 4 and 9, in the first groove H1, the first trench isolation portion DTI may be formed, and the anti-reflection layer ARP may be formed on the photodiode PD. The first trench isolation portion DTI serves to totally reflect light incident on the first trench isolation portion DTI to the photodiode PD. The first trench isolation portion DTI serves to totally reflect the light to the photodiode PD or, to scatter the light, thereby increasing the path of the light. As a result, the first trench isolation portion DTI may serve to improve the quantum efficiency of the photodiode PD.

The anti-reflection layer ARP may include a material which is the same as the material of the first trench isolation portion DTI. The anti-reflection layer ARP may be formed in the same manufacture process as the manufacture process of the first trench isolation portion DTI, and may be integrally connected with the first trench isolation portion DTI. The anti-reflection layer ARP may serve to prevent the light incident on the light concentrating pattern MLP from being totally reflected in the photodiode PD. To this end, the anti-reflection layer ARP may have a refractive index between a refractive index of the color filters CF_G and CF_R and a refractive index of the photodiode PD, but is not limited thereto. For example, the refractive index of the anti-reflection layer ARP may be about 1.4 to 2.0, but is not limited thereto. The anti-reflection layer ARP may be disposed throughout the pixel regions PX_R and PX_G1, and the non-pixel region NPX.

As illustrated in FIGS. 4 and 10, the carbon layer CL is formed on the anti-reflection layer ARP, and a stopper layer SL′ is formed on the carbon layer CL. The carbon layer CL may include carbon, and the stopper layer SL may include silicon nitride (SiNx).

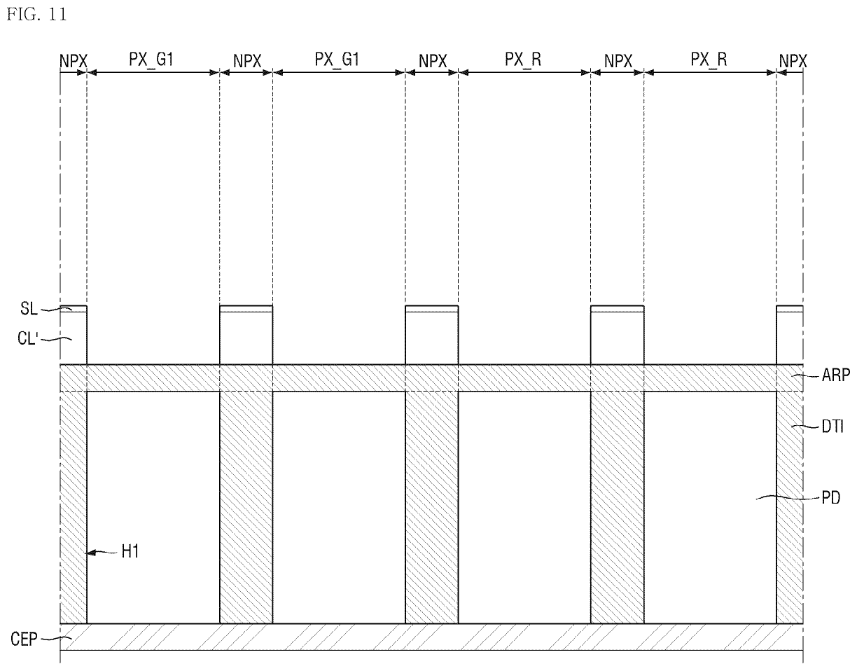

As illustrated in FIGS. 4 and 11, a carbon layer CL′ and the stopper layer SL as illustrated in FIG. 11 are formed by removing the carbon layer CL (refer to CL in FIG. 10) and the stopper layer SL′ (refer to SL′ in FIG. 10) in the pixel regions PX_G1 and PX_R. The carbon layer CL′ and the stopper layer SL may be disposed in the non-pixel region NPX.

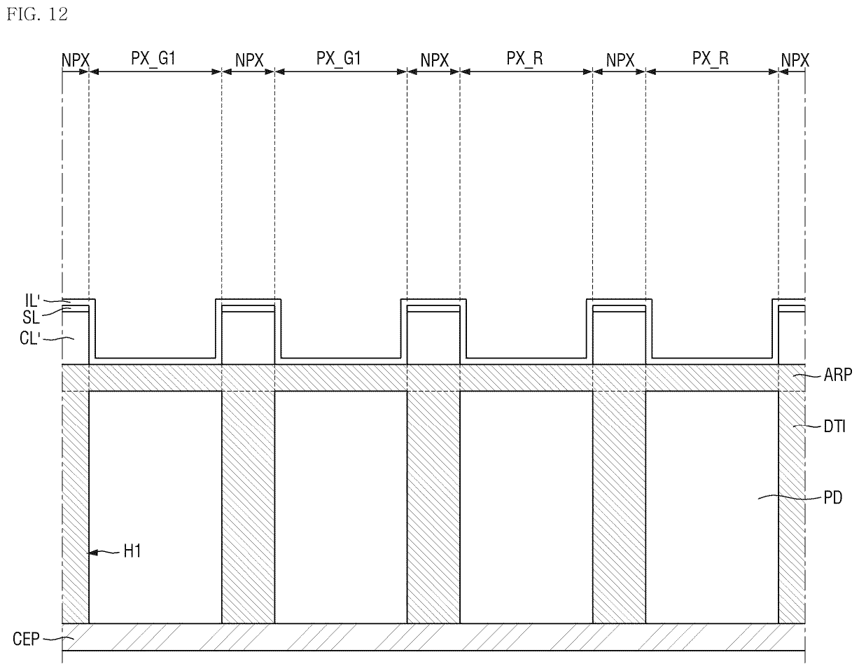

As illustrated in FIGS. 4 and 12, the insulation layer IL is formed on a side surface of the carbon layer CL′, a side surface and an upper surface of the stopper layer SL, and an exposed upper surface of the anti-reflection layer ARP. The insulation layer IL may include silicon oxide (SiO₂), but is not limited thereto.

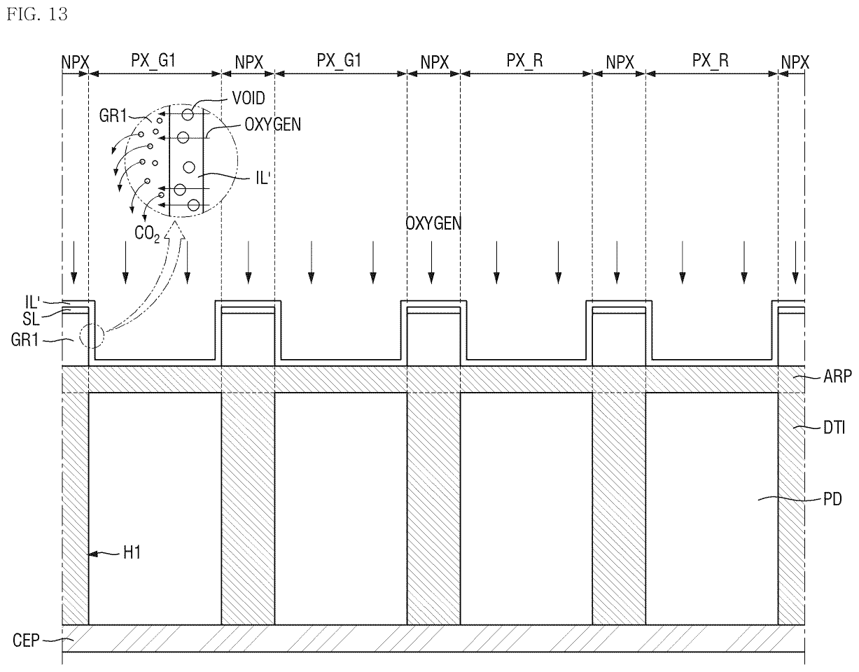

As illustrated in FIGS. 4 and 13, the carbon layer CL′ is oxidized using oxygen. Oxygen passes through a void (or a pore) positioned inside the insulation layer IL and oxidizes the carbon layer CL′ to generate carbon dioxide (CO2). When the carbon layer CL′ is oxidized, the air structure may remain in a region in which the carbon layer CL′ has been formed. By oxidizing the carbon layer CL′ using oxygen, the first grid portion GR1 is formed.

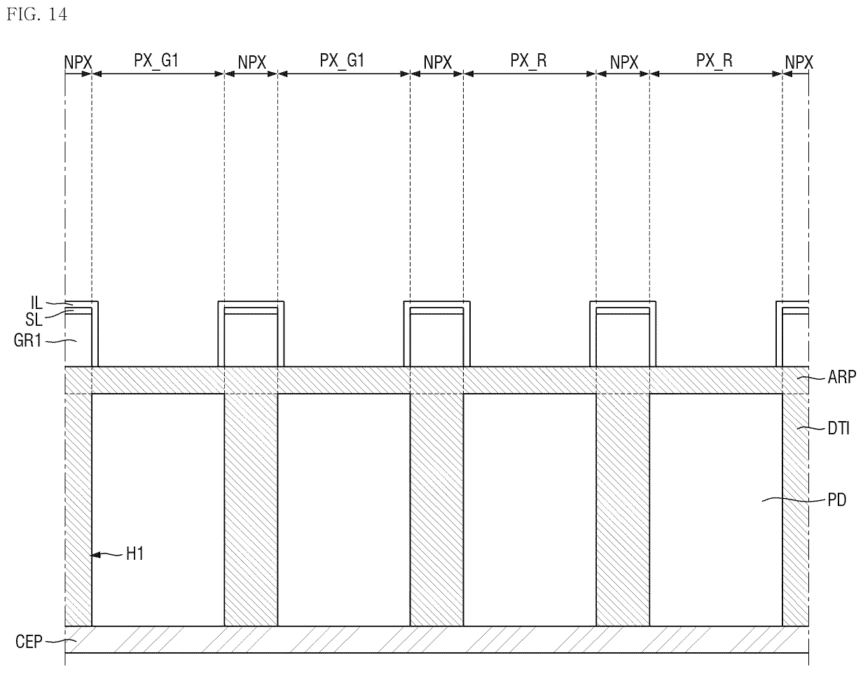

As illustrated in FIGS. 4 and 14, the insulation layer IL is formed. The insulation layer IL may be formed by removing the insulation layer IL′ (refer to IL′ in FIG. 13) in the pixel regions PX_G1 and PX_R.

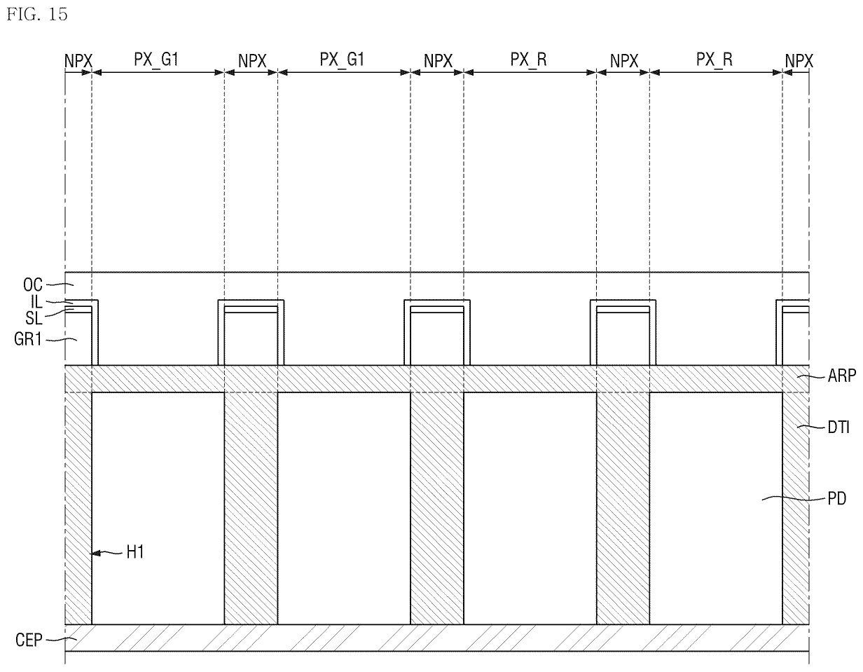

As illustrated in FIGS. 4 and 15, the planarization layer OC is disposed on the first grid portion GR1 and the anti-reflection layer ARP. The planarization layer OC may include an organic insulation material. However, the disclosed technology is not limited thereto, and the planarization layer OC may include an inorganic insulation material. The first grid portion GR1 may be embedded in the planarization layer OC. The planarization layer OC may be disposed throughout the pixel regions PX_G1 and PX_R and the non-pixel region NPX. The planarization layer OC may directly contact an upper surface of the anti-reflection layer ARP and the insulation layer IL. The planarization layer OC may be disposed between the insulation layer IL and the second grid portion GR2 in the non-pixel region NPX. However, the disclosed technology is not limited thereto, and the planarization layer OC may not be disposed between the insulation layer IL and the second grid portion GR2 in the non-pixel region NPX.

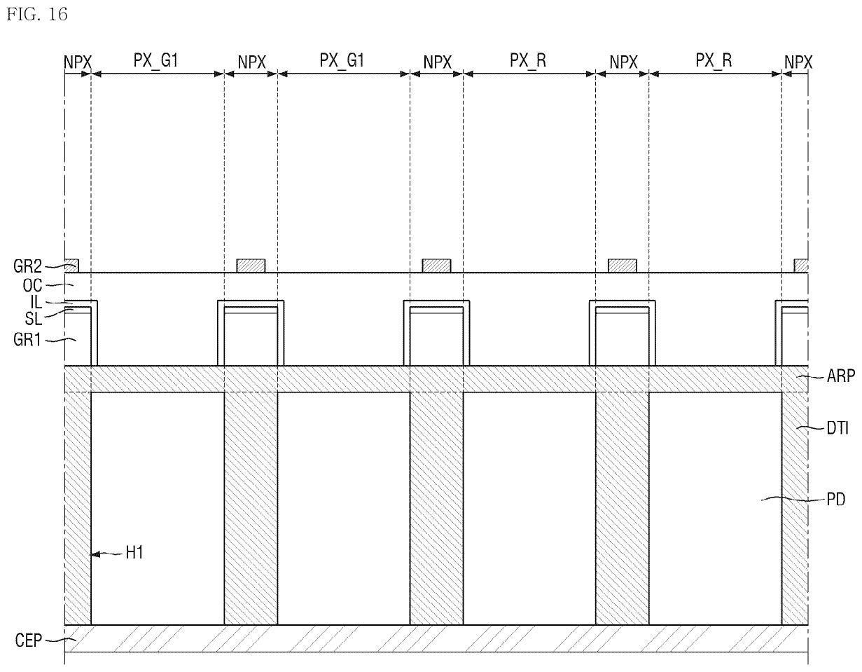

As illustrated in FIGS. 4 and 16, the second grid portion GR2 is disposed on the planarization layer OC in the non-pixel region NPX. The second grid portion GR2 may include a metal material. The second grid portion GR2 may overlap the first grid portion GR1 in a thickness direction.

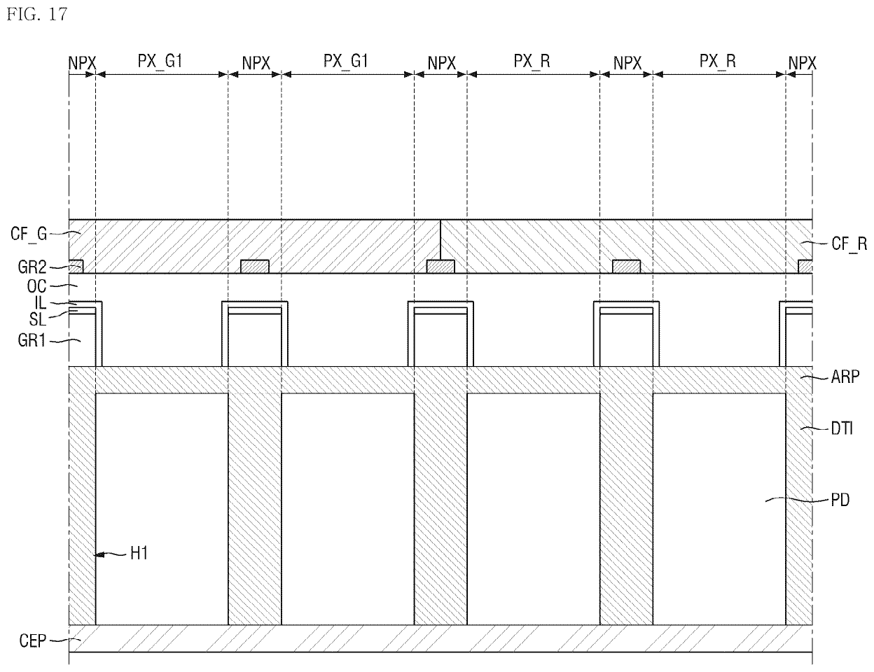

As illustrated in FIGS. 4 and 17, the color filters CF_G and CF_R are disposed on the second grid portion GR2 and the planarization layer OC. The first color filter CF_G may receive light in a green wavelength range and an ultraviolet wavelength range, and block light in the remaining wavelength ranges. The second color filter CF_R may receive light in a red wavelength range and an ultraviolet wavelength range, and block light in the remaining wavelength ranges.

Hereinafter, a pixel array of an image sensing device according to another embodiment will be described. With respect to the reference numerals or components which have been described referring to FIGS. 1 to 27, the redundant description thereof or the detailed description thereof will be omitted.

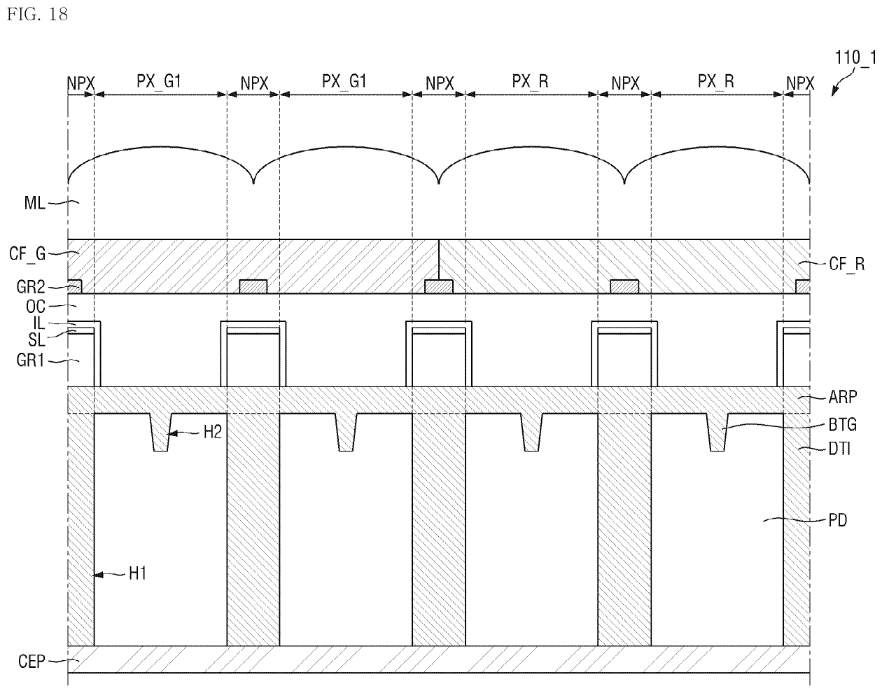

FIG. 18 is a cross-sectional view of a pixel array of an image sensing device based on another embodiment of the disclosed technology.

Referring to FIG. 18, a second groove H2 may be formed in the photodiode PD of the pixel array 110_1 of the image sensing device based on an embodiment, and one or two second grooves H2, or three or more second grooves H2 may be disposed in the pixel regions PX_G1 and PX_R. In the second groove H2, the second trench isolation portion BTG (back side trench guide) may be formed, and therefore, one or two second trench isolation portions BTG may be provided, or three or more second trench isolation portions BTG may be disposed in the pixel regions PX_G1 and PX_R. The first trench isolation portion DTI and the second trench isolation portion may include the same material. For example, the first trench isolation portion DTI and the second trench isolation portion BTG may include an insulation material. For example, an example of the insulation material is hafnium oxide (HfO2), or silicon oxide (SiO₂), but is not limited thereto. The second trench isolation portion BTG serves to scatter light incident on the light concentrating pattern ML. The first trench isolation portion DTI and the second trench isolation portion BTG may serve to increase a path of the light by totally reflecting the light to the photodiode PD or scattering the light. As a result, the trench isolation portion may serve to improve a quantum efficiency of the photodiode PD.

The description of other components, which have been provided referring to FIG. 4, will be omitted.

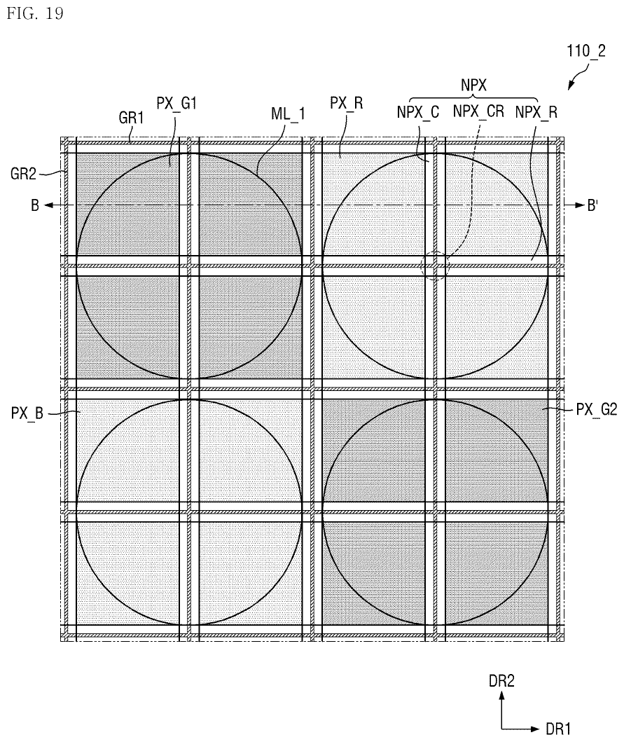

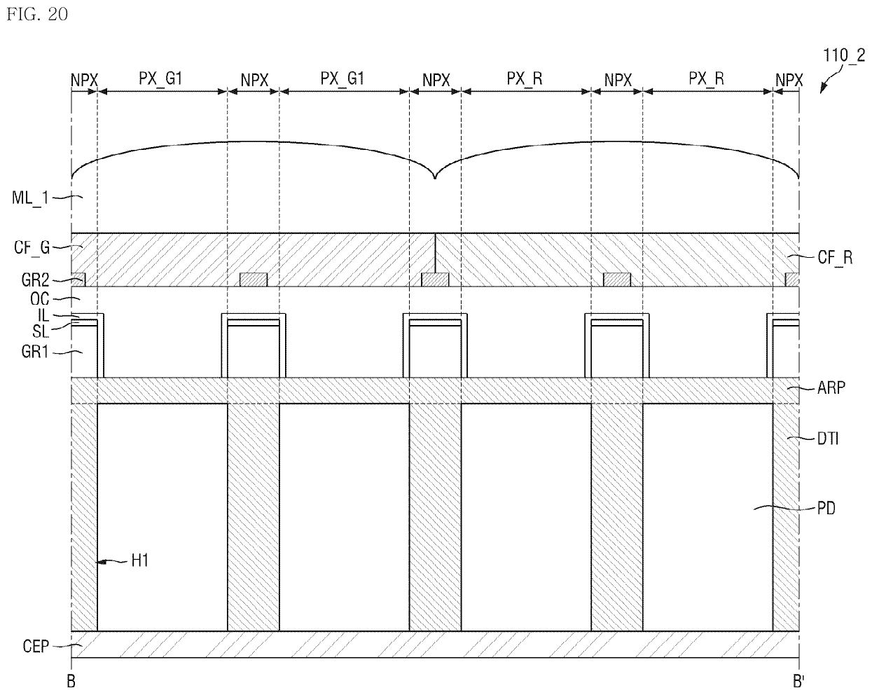

FIG. 19 is a plan view illustrating an example of a pixel array of an image sensing device based on another embodiment of the disclosed technology. FIG. 20 is a cross-sectional view taken along line B-B′ of FIG. 19.

Referring to FIGS. 19 and 20, a light concentrating pattern ML_1 of a pixel array 110_2 according to the present embodiment is different from the pixel array 110 according to FIGS. 3 and 4 in that the light concentrating pattern ML_1 of the pixel array 110_2 is disposed in correspondence with the grouped pixels.

To describe it in more detail, one light concentrating pattern ML_1 is disposed on four first pixels, one light concentrating pattern ML_1 is disposed on four second pixels, one light concentrating pattern ML_1 is disposed on four third pixels, and one light concentrating pattern ML_1 is disposed on four fourth pixels.

The description of other components, which have been provided referring to FIGS. 3 and 4, will be omitted.

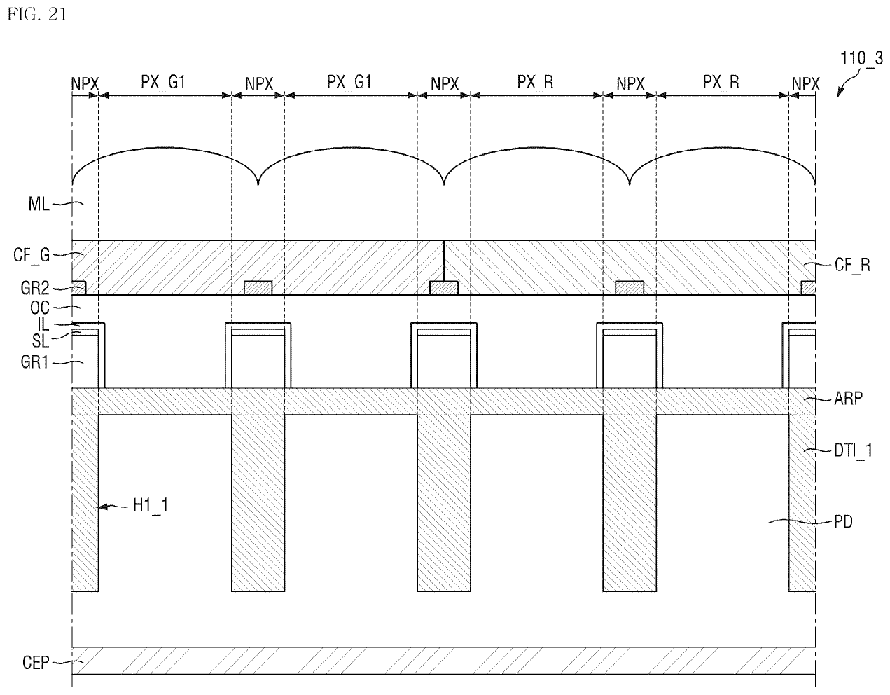

FIG. 21 is a cross-sectional view of a pixel array of an image sensing device based on another embodiment of the disclosed technology.

Referring to FIG. 21, a pixel array 110_3 is different from the pixel array 110 illustrated in FIG. 4 in that a first groove H1_1 partially passes through the photodiode PD.

In some implementations, the first groove H1_1 passes through the photodiode PD in a thickness direction from the upper surface of the photodiode PD, but the first groove H1_1 may not completely pass through the photodiode PD. The first trench isolation portion DTI_1 is disposed in the first groove H1_1, and a bottom surface of the first trench isolation portion DTI_1 may directly contact the photodiode PD.

The description of other components, which have been provided referring to FIG. 4, will be omitted.

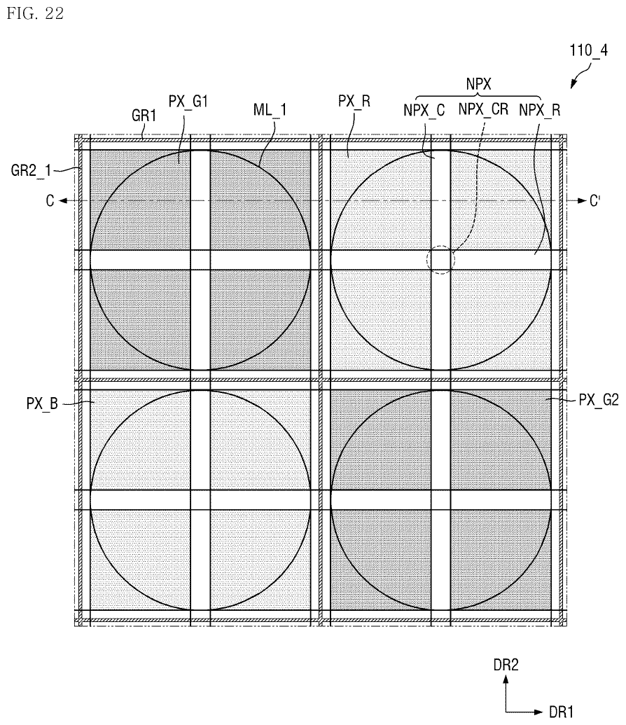

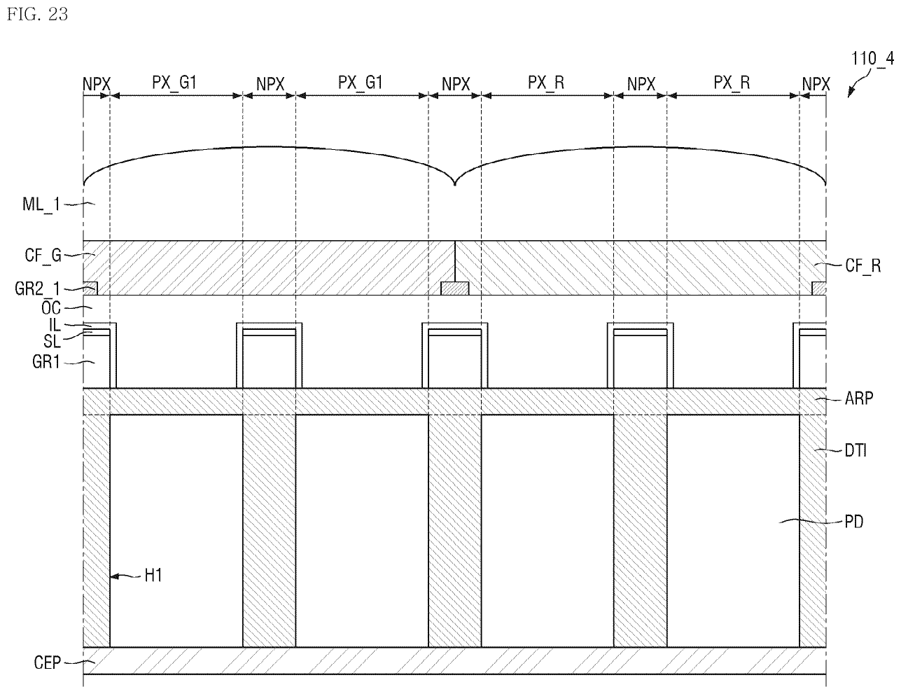

FIG. 22 is a plan view illustrating an example of a pixel array of an image sensing device based on another embodiment of the disclosed technology. FIG. 23 is a cross-sectional view taken along line C-C′ of FIG. 22.

Referring to FIGS. 22 and 23, a pixel array 110_4 is different from the pixel array 110 illustrated in FIGS. 3 and 4 in that a second grid portion GR2_1 is disposed in a boundary between the grouped pixels, but is not disposed in the grouped pixels. In addition, as illustrated in FIGS. 19 and 20, the pixel array 110_4 is different from the pixel array 110 illustrated in FIGS. 3 and 4 in that the light concentrating pattern ML_1 of the pixel array 110_4 is disposed in correspondence with the grouped pixels.

One light concentrating pattern ML_1 is disposed on four first pixels, one light concentrating pattern ML_1 is disposed on four second pixels, one light concentrating pattern ML_1 is disposed on four third pixels, and one light concentrating pattern ML_1 is disposed on four fourth pixels.

The first grid portion GR1 is disposed in a boundary between the first pixel regions PX_G1, but the second grid portion GR2 is not disposed in the boundary between the first pixel regions PX_G1. In contrast, the first grid portion GR1 and the second grid portion GR2 may be disposed together in a boundary between the first pixel regions PX_G1 and the second pixel regions PX_R.

The description of other components, which have been provided referring to FIGS. 3 and 4, will be omitted.

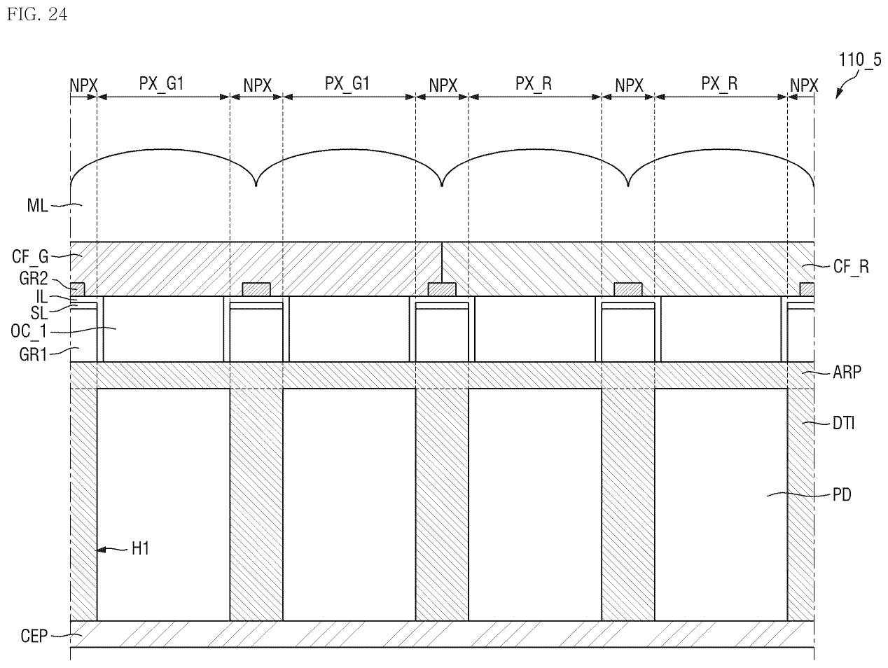

FIG. 24 is a cross-sectional view of a pixel array of an image sensing device based on another embodiment of the disclosed technology.

Referring to FIG. 24, a pixel array 110_5 is different from the pixel array 110 illustrated in FIG. 4 in that a surface of a planarization layer OC_1 of the pixel array 110_5 is positioned to be collinear with a surface of the insulation layer IL.

In some implementations, a surface height of the planarization layer OC_1 may be the same as a surface height of the insulation layer IL.

A thickness (or a surface height) of the planarization layer OC_1 implemented based on an embodiment may be adjusted according to a size of a pixel. For example, if the size of the pixel is small, a distance between the light concentrating pattern ML and the photodiode PD must be small so that the light concentrated from the light concentrating pattern ML can be well focused in the photodiode PD. On the other hand, if the size of the pixel is large, the distance between the light concentrating pattern ML and the photodiode PD must be large so that the light concentrated from the light concentrating pattern ML can be well focused in the photodiode PD.

In addition, in an embodiment, because the surface height of the planarization layer OC_1 is the same as the surface height of the insulation layer IL, the first grid portion GR1 and the second grid portion GR2 may be positioned close to each other. That is, the stopper layer SL and the second grid portion GR2 may interpose the insulation layer IL therebetween. The insulation layer IL may directly contact the second grid portion GR2. Accordingly, the light color mixing between neighboring pixels can be prevented.

The description of other components, which have been provided referring to FIG. 4, will be omitted.

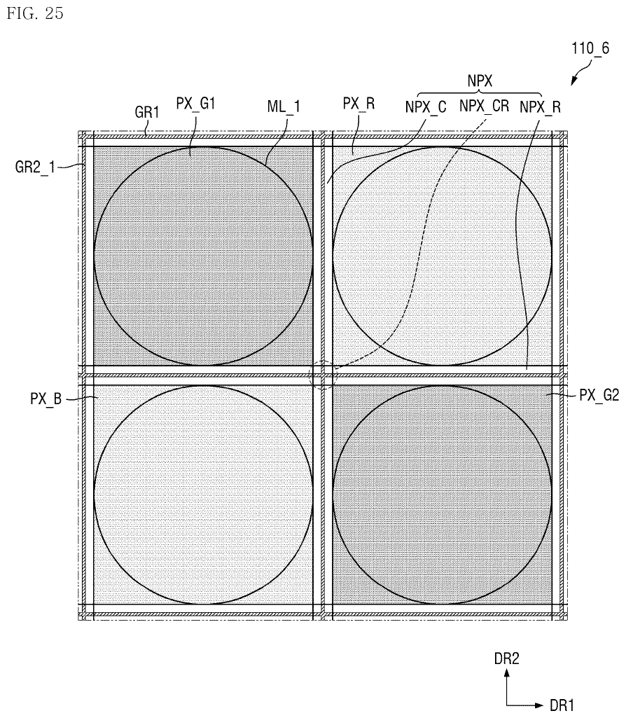

FIG. 25 is a plan view illustrating an example of a pixel array of an image sensing device based on another embodiment of the disclosed technology.

Referring to FIG. 25, a pixel array 110_6 is different from the pixel array 110 illustrated in FIG. 3 in that each pixel of the pixel array 110_6 includes only one pixel.

In some implementations, the first pixel, the second pixel, the third pixel, and the fourth pixel may not be grouped in the pixel array 110_6. The non-pixel region NPX may be formed between neighboring pixels. For example, the non-pixel region NPX may be formed in boundaries between the first pixel, the second pixel, the third pixel, and the fourth pixel.

The description of other components, which have been provided referring to FIG. 3, will be omitted.

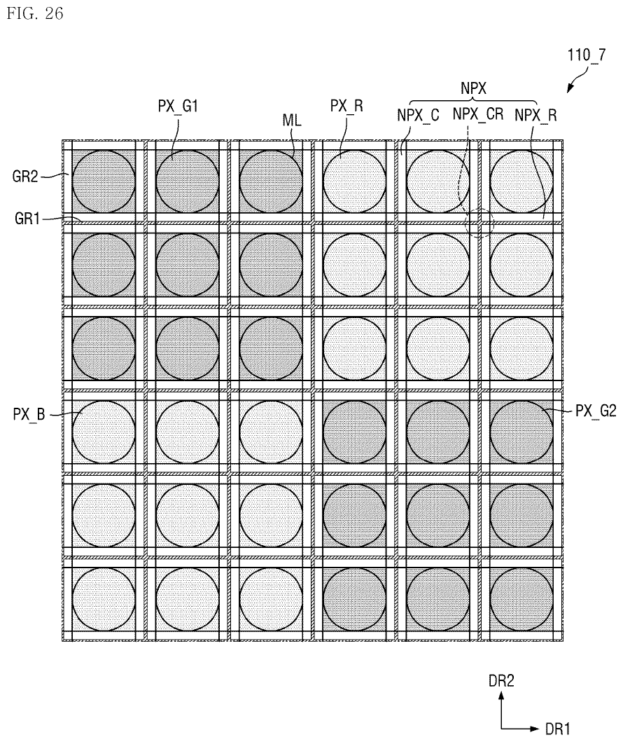

FIG. 26 is a plan view illustrating an example of a pixel array of an image sensing device based on another embodiment of the disclosed technology.

Referring to FIG. 26, each pixel in a pixel array 110_7 based on an embodiment may be grouped into a plurality of groups. For example, nine pixels may be grouped and disposed. For example, as illustrated in FIG. 26, the first pixel, the second pixel, the third pixel, and the fourth pixel may be grouped by a nine-pixel unit. For example, each pixel may be disposed in a three-by-three array configuration, but the disclosed technology is not limited thereto.

For example, three grouped first pixels may be disposed along a row direction (or a first direction DR1) and a column direction (or a second direction DR2), three grouped second pixels may be disposed along the row direction (or the first direction DR1) and the column direction (or the second direction DR2), three grouped third pixels may be disposed along the row direction (or the first direction DR1) and the column direction (or the second direction DR2), and three grouped fourth pixels may be disposed along the row direction (or the first direction DR1) and the column direction (or the second direction DR2). The grouped first pixels, the grouped second pixels, the grouped third pixels, and the grouped fourth pixels may be disposed in a matrix configuration. That is, the grouped first pixels, the grouped second pixels, the grouped third pixels, and the grouped fourth pixels may be disposed along the row direction (or the first direction DR1) and the column direction (or the second direction DR2) in a matrix configuration.

The non-pixel region NPX may be formed between neighboring pixels. For example, the non-pixel region NPX may be disposed in boundaries between the grouped first pixels, the grouped second pixels, the grouped third pixels, and the grouped fourth pixels, and in boundaries between the grouped first pixels, between the grouped second pixels, between the grouped third pixels, and between the grouped fourth pixels.

For example, the non-pixel region NPX may include a first non-pixel region NPX_R extending along the row direction (or the first direction DR1), a second non-pixel region NPX_C extending along the column direction (or the second direction DR2), and a third non-pixel region NPX_CR extending in a boundary between the first non-pixel region NPX_R and the second non-pixel region NPX_C.

The first non-pixel region NPX_R may extend along a boundary between the grouped first pixels and the grouped third pixels and a boundary between the grouped second pixels and the grouped fourth pixels, and along an internal boundary (a boundary extending along the first direction DR1) of each of the grouped first pixels, the grouped second pixels, the grouped third pixels, and the grouped fourth pixels.

The second non-pixel region NPX_C may extend along a boundary between the grouped first pixels and the grouped third pixels and a boundary between the grouped second pixels and the grouped fourth pixels, and along an internal boundary (a boundary extending along the second direction DR2) of each of the grouped first pixels, the grouped second pixels, the grouped third pixels, and the grouped fourth pixels.

The description of other components, which have been provided referring to FIG. 3, will be omitted.

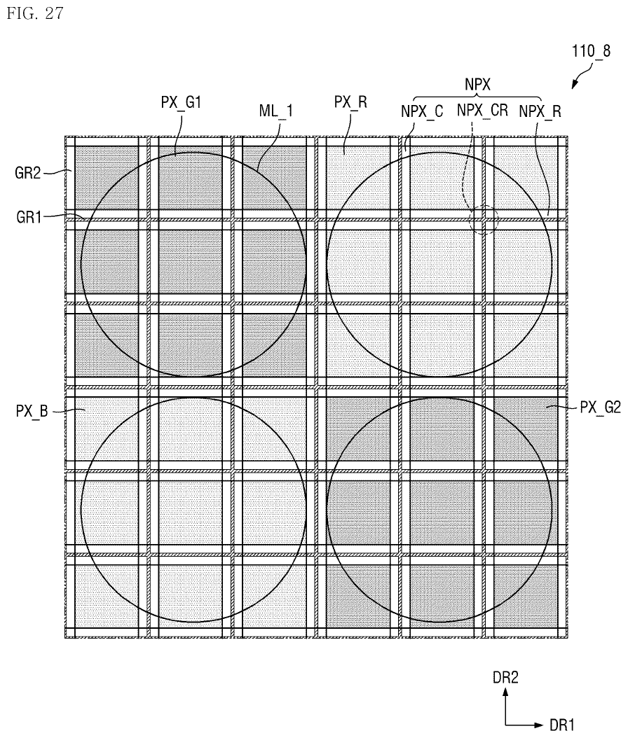

FIG. 27 is a plan view illustrating an example of a pixel array of an image sensing device based on another embodiment of the disclosed technology.

Referring to FIG. 27, a pixel array 110_8 is different from the pixel array 110_7 illustrated in FIG. 26 in that the light concentrating pattern ML_1 of the pixel array 110_8 is disposed in correspondence with the grouped pixels.

In some implementations, one light concentrating pattern ML_1 is disposed on nine first pixels, one light concentrating pattern ML_1 is disposed on nine second pixels, one light concentrating pattern ML_1 is disposed on nine third pixels, and one light concentrating pattern ML_1 is disposed on nine fourth pixels.

The description of other components, which have been provided referring to FIG. 26, will be omitted.

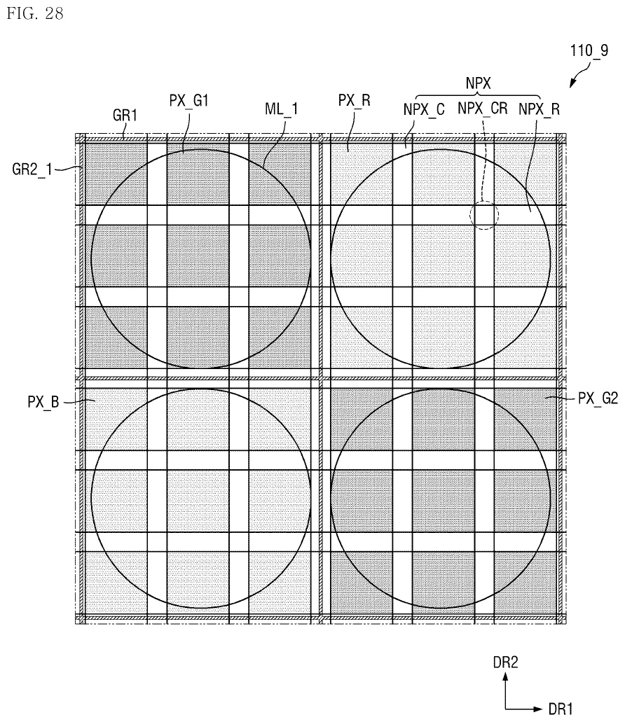

FIG. 28 is a plan view illustrating an example of a pixel array of an image sensing device based on another embodiment of the disclosed technology.

Referring to FIG. 28, a pixel array 110_9 is different from the pixel array 110_8 illustrated in FIG. 27 in that second grid portion GR2_1 is disposed in a boundary between the grouped pixels, but is not disposed in the grouped pixels. In addition, the light concentrating pattern ML_1 may be disposed in correspondence with the grouped pixels.

One light concentrating pattern ML_1 is disposed on nine first pixels, one light concentrating pattern ML_1 is disposed on nine second pixels, one light concentrating pattern ML_1 is disposed on nine third pixels, and one light concentrating pattern ML_1 is disposed on nine fourth pixels.

For example, the first grid portion GR 1 may be disposed in the boundary between the first pixel regions PX_G1, however, the second grid portion GR2 may not be disposed in the boundary between the first pixel regions PX_G1. On contrary, the first grid portion GR1 and the second grid portion GR2 may be disposed together in a boundary between the first pixel regions PX_G1 and the second pixel regions PX_R.

The description of other components, which have been provided referring to FIG. 27, will be omitted.

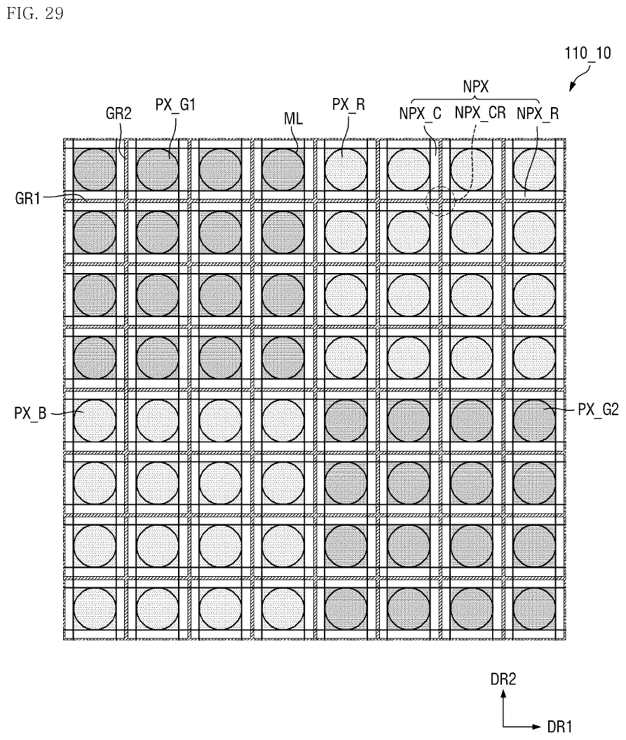

FIG. 29 is a plan view illustrating an example of a pixel array of an image sensing device based on another embodiment of the disclosed technology.

Referring to FIG. 29, each pixel in a pixel array 110_10 according to the present embodiment may be grouped into a plurality of groups. For example, nine pixels may be grouped and disposed. For example, as illustrated in FIG. 29, the first pixel, the second pixel, the third pixel, and the fourth pixel may be grouped by a sixteen-pixel unit. For example, each pixel may be disposed in a three-by-three arrangement, but the disclosed technology is not limited thereto.

For example, four grouped first pixels may be disposed along a row direction (or a first direction DR1) and a column direction (or a second direction DR2), four grouped second pixels may be disposed along the row direction (or the first direction DR1) and the column direction (or the second direction DR2), four grouped third pixels may be disposed along the row direction (or the first direction DR1) and the column direction (or the second direction DR2), and four grouped fourth pixels may be disposed along the row direction (or the first direction DR1) and the column direction (or the second direction DR2). The grouped first pixels, the grouped second pixels, the grouped third pixels, and the grouped fourth pixels may be disposed in a matrix form. That is, the grouped first pixels, the grouped second pixels, the grouped third pixels, and the grouped fourth pixels may be disposed along the row direction (or the first direction DR1) and the column direction (or the second direction DR2) in a matrix form.

The non-pixel region NPX may be formed between neighboring pixels. For example, the non-pixel region NPX may be disposed not only in boundaries between the grouped first pixels, the grouped second pixels, the grouped third pixels, and the grouped fourth pixels, but also in boundaries between the grouped first pixels, between the grouped second pixels, between the grouped third pixels, and between the grouped fourth pixels.

For example, the non-pixel region NPX may include a first non-pixel region NPX_R extending along the row direction (or the first direction DR1), a second non-pixel region NPX_C extending along the column direction (or the second direction DR2), and a third non-pixel region NPX_CR extending in a boundary between the first non-pixel region NPX_R and the second non-pixel region NPX_C.

The first non-pixel region NPX_R may extend not only along a boundary between the grouped first pixels and the grouped third pixels and a boundary between the grouped second pixels and the grouped fourth pixels, but also along an internal boundary (a boundary extending along the first direction DR1) of each of the grouped first pixels, the grouped second pixels, the grouped third pixels, and the grouped fourth pixels.

The second non-pixel region NPX_C may extend not only along a boundary between the grouped first pixels and the grouped third pixels and a boundary between the grouped second pixels and the grouped fourth pixels, but also along an internal boundary (a boundary extending along the second direction DR2) of each of the grouped first pixels, the grouped second pixels, the grouped third pixels, and the grouped fourth pixels.

The description of other components, which have been provided referring to FIG. 3, will be omitted.

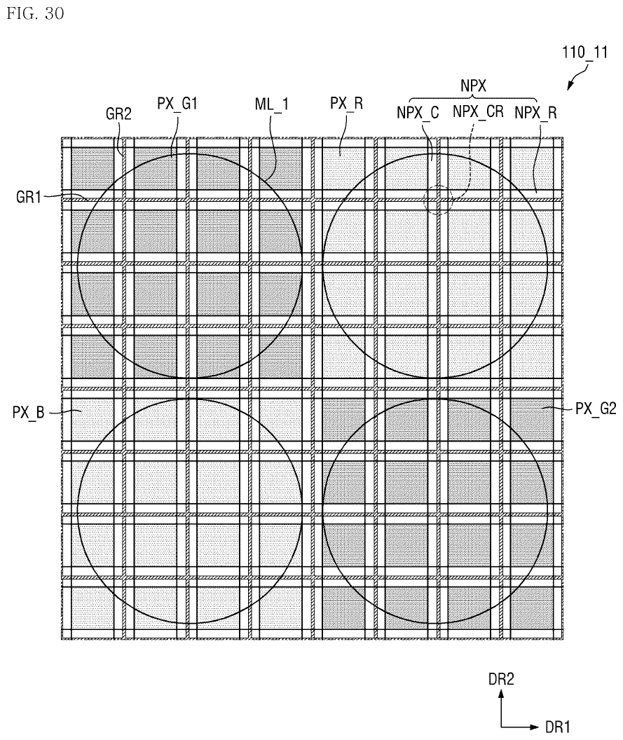

FIG. 30 is a plan view illustrating an example of a pixel array of an image sensing device based on another embodiment of the disclosed technology.

Referring to FIG. 30, a pixel array 110_11 according to the present embodiment is different from the pixel array 110_10 according to FIG. 29 in that the light concentrating pattern ML_1 of the pixel array 110_11 is disposed in correspondence with the grouped pixels.

In some implementations, one light concentrating pattern ML_1 is disposed on sixteen first pixels, one light concentrating pattern ML_1 is disposed on sixteen second pixels, one light concentrating pattern ML_1 is disposed on sixteen third pixels, and one light concentrating pattern ML_1 is disposed on sixteen fourth pixels.

The description of other components, which have been provided referring to FIG. 29, will be omitted.

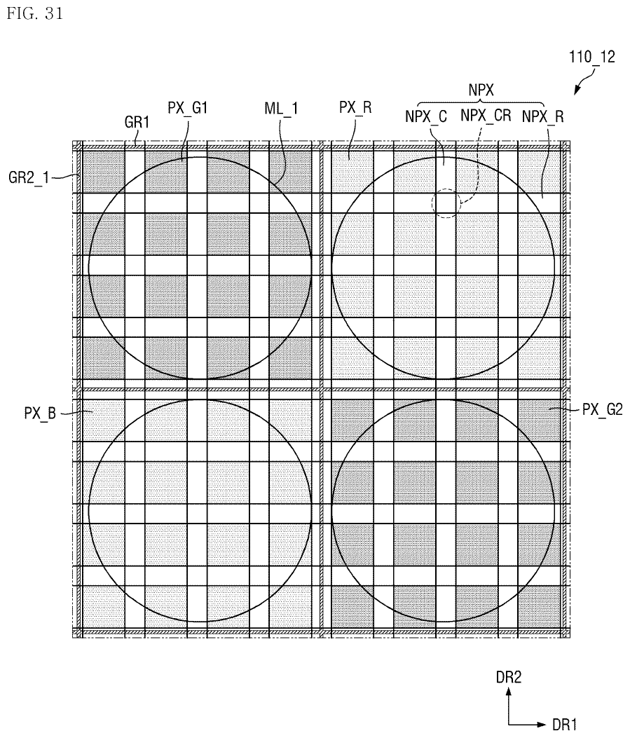

FIG. 31 is a plan view illustrating an example of a pixel array of an image sensing device based on another embodiment of the disclosed technology.

Referring to FIG. 31, a pixel array 110_12 is different from the pixel array 110_11 illustrated in FIG. 30 in that the second grid portion GR2_1 is disposed in a boundary between the grouped pixels, but is not disposed in the grouped pixels. In addition, the light concentrating pattern ML_1 may be disposed in correspondence with the grouped pixels.

One light concentrating pattern ML_1 is disposed on sixteen first pixels, one light concentrating pattern ML_1 is disposed on sixteen second pixels, one light concentrating pattern ML_1 is disposed on sixteen third pixels, and one light concentrating pattern ML_1 is disposed on sixteen fourth pixels.

For example, the first grid portion GR1 may be disposed in a boundary between the first pixel regions PX_G1, but the second grid portion GR2 may not be disposed in the boundary between the first pixel regions PX_G1. On contrary, the first grid portion GR1 and the second grid portion GR2 may be disposed together in a boundary between the first pixel regions PX_G1 and the second pixel regions PX_R.

The description of other components, which have been provided referring to FIG. 30, will be omitted.

The image sensing device according to the various embodiments of the present disclosure may be described as below.

In an embodiment, an image sensing device may include: a circuitry region that includes a pixel region and a non-pixel region disposed around the pixel region; a photodiode on the circuitry region; an anti-reflection layer on the photodiode; a first grid portion disposed on the anti-reflection layer in the non-pixel region; a planarization layer on the first grid portion and the anti-reflection layer; and a color filter on the planarization layer, and the first grid portion may include an air structure.

In some embodiments of the disclosed technology, the image sensing device may further include: a second grid portion disposed between the planarization layer and the color filter in the non-pixel region.

In some embodiments of the disclosed technology, the second grid portion may include a metal material.

In some embodiments of the disclosed technology, a width of the second grid portion may be smaller than a width of the first grid portion.

In some embodiments of the present disclosure, the image sensing device may further include: a first groove configured to pass through the photodiode in the non-pixel region; and a trench isolation portion disposed in the first groove.

In some embodiments of the present disclosure, the first groove may be configured to completely pass through the photodiode.

In some embodiments of the disclosed technology, the trench isolation portion may include a same material as a material of the anti-reflection layer.

In some embodiments of the disclosed technology, the image sensing device may further include: a stopper layer between the first grid portion and the color filter; and an insulation layer configured to cap the first grid portion and the stopper layer.

In some embodiments of the disclosed technology, the pixel region may be provided in plurality, the plurality of pixel regions may include a red pixel region, a first green pixel region, a second green pixel region, and a blue pixel region, and the non-pixel region may be positioned in a boundary between the plurality of pixel regions.

In some embodiments of the disclosed technology, the image sensing device may further include: a light concentrating pattern disposed on the color filter.

In some embodiments of the disclosed technology, the light concentrating pattern may be disposed in each pixel region.

In an image sensing device according to various embodiments of the disclosed technology, each of the red pixel region, the first green pixel region, the second green pixel region, and the blue pixel region may include same sub-color pixel regions. The sub-color pixel regions may be grouped to form the red pixel region, the first green pixel region, the second green pixel region, and the blue pixel region, respectively.

In some embodiments of the disclosed technology, the same sub-color pixel regions may be disposed in a two-by-two arrangement.

In some embodiments of the disclosed technology, the same sub-color pixel regions may be disposed in a three-by-three arrangement.

In some embodiments of the disclosed technology, the same sub-color-pixel regions may be disposed in a four-by-four arrangement.

In some embodiments of the disclosed technology, one light concentrating pattern may be disposed in the same sub-color pixel regions.

In some embodiments of the disclosed technology, the planarization layer may include an organic insulation material or an inorganic insulation material.

In another embodiment, a method for manufacturing an image sensing device may include: forming a photodiode on a circuitry region that includes a pixel region and a non-pixel region disposed around the pixel region; forming a trench isolation portion in the non-pixel region inside the photodiode into which a photodiode layer is etched; forming an anti-reflection layer on the photodiode; forming a carbon layer and a stopper layer on the anti-reflection layer; etching the carbon layer and the stopper layer except the non-pixel region; forming a first insulation layer on the etched carbon layer and the etched stopper layer; and oxidizing the carbon layer and forming a first grid portion in the non-pixel region.

In some embodiments of the disclosed technology, the forming a trench isolation portion in the non-pixel region inside the photodiode into which a photodiode layer is etched and the forming an anti-reflection layer on the photodiode may be performed simultaneously.

In some embodiments of the disclosed technology, the method may further include forming a planarization layer on the insulation layer and the anti-reflection layer.

In some embodiments of the disclosed technology, the method may further include forming a second grid portion on the planarization layer in the non-pixel region, and the second grid portion may include a metal material.

In some embodiments of the disclosed technology, the method may further include forming a color filter on the planarization layer and the second grid portion.

Only a few implementations and examples are described and other implementations, enhancements and variations can be made based on what is described and illustrated in this patent document.

What is claimed is:

1. An image sensing device, comprising:
a circuitry region including a plurality of pixel regions detecting structured to capture images in incident light and a plurality of non-pixel regions, each of the plurality of non-pixel regions disposed between adjacent pixel regions of the plurality of pixel regions;
a plurality of photodetectors disposed in the plurality of pixel regions and structured to detect incident light for capturing images in the detected incident light;
a plurality of trench isolation portions disposed in the plurality of non-pixel regions, each of plurality of trench isolation portions disposed between adjacent photodetectors of the plurality of photodetectors;
an anti-reflection layer disposed on the plurality of photodetectors in the plurality of pixel regions and on the plurality of trench isolation portions in the plurality of non-pixel regions;
a first grid portion disposed on the anti-reflection layer disposed on each of the plurality of trench isolation portions in each of the plurality of non-pixel regions;
a planarization layer disposed on the first grid portion in the plurality of non-pixel regions and the anti-reflection layer in the plurality of pixel regions; and
a color filter on the planarization layer,
wherein the first grid portion includes air.

2. The image sensing device of claim 1, further comprising:
a second grid portion disposed below the color filter in each of the plurality of non-pixel regions and over the planarization layer disposed on the first grid portion in each of the plurality of non-pixel regions.

3. The image sensing device of claim 2, wherein the second grid portion includes a metal material.

4. The image sensing device of claim 3, wherein a width of the second grid portion is smaller than a width of the first grid portion.

5. The image sensing device of claim 1, wherein each of the plurality of trench isolation portions includes a dielectric material filling a first groove formed in the non-pixel region.

6. The image sensing device of claim 5, wherein the first groove is formed in the non-pixel region between adjacent photodetectors.

7. The image sensing device of claim 5, wherein the trench isolation portion includes a same material as a material of the anti-reflection layer.

8. The image sensing device of claim 1, further comprising:
an etching stopper layer between the first grid portion and the color filter; and
an insulation layer configured to cover the first grid portion and the etching stopper layer.

9. The image sensing device of claim 1, wherein the plurality of pixel regions comprises a red pixel region, a first green pixel region, a second green pixel region, and a blue pixel region, and
wherein each of the plurality of non-pixel regions is positioned in a boundary between adjacent pixel regions of the plurality of pixel regions.

10. The image sensing device of claim 9, further comprising:
a light concentrating pattern disposed on the color filter and structured to direct light toward the plurality of pixel regions.

11. The image sensing device of claim 10, wherein the light concentrating pattern is disposed in each of the plurality of pixel regions.

12. The image sensing device of claim 10, wherein each of the red pixel region, the first green pixel region, the second green pixel region, and the blue pixel region comprises same sub-color pixel regions.

13. The image sensing device of claim 12, wherein the same sub-color pixel regions are disposed in a two-by-two, three-by-three, or four-by-four array configuration.

14. The image sensing device of claim 12, wherein one light concentrating pattern is disposed in the same sub-color pixel regions.

15. The image sensing device of claim 1, wherein the planarization layer comprises an organic insulation material or an inorganic insulation material.

16. An image sensing device, comprising:
a circuitry region including a plurality of pixel regions and a plurality of non-pixel regions, each of the plurality of non-pixel regions disposed between adjacent pixel regions of the plurality of pixel regions;
a plurality of photodetectors disposed in the plurality of pixel regions;
an anti-reflection layer disposed on the plurality of photodetectors in the plurality of pixel regions and on a plurality of trench isolation portions in the plurality of non-pixel regions;
a first grid portion disposed on the anti-reflection layer disposed on each of the plurality of trench isolation portions in each of the plurality of non-pixel regions;
a color filter over the first grid portion; and
a second grid portion disposed below the color filter in each of the plurality of non-pixel regions and over the first grid portion,
wherein the first grid portion includes air.

17. The image sensing device of claim 16, wherein the second grid portion includes a metal material.

18. The image sensing device of claim 17, wherein a width of the second grid portion is smaller than a width of the first grid portion.

19. The image sensing device of claim 16, wherein the plurality of pixel regions comprises a red pixel region, a first green pixel region, a second green pixel region, and a blue pixel region, wherein each of the red pixel region, the first green pixel region, the second green pixel region, and the blue pixel region comprises same sub-color pixel regions.

20. The image sensing device of claim 19, wherein the same sub-color pixel regions are disposed in a two-by-two, three-by-three, or four-by-four array configuration, and
wherein one light concentrating pattern is disposed in the same sub-color pixel regions.
